(19) United States
(12) Patent Application Publication
(10) Pub. No.: US 2024/0184948 A1
(43) Pub. Date: Jun. 6, 2024

(54) DEFINING AND TESTING EVOLVING EVENT SEQUENCES

(71) Applicant: Motional AD LLC, Boston, MA (US)

(72) Inventors: Li Shu, Englewood, CO (US); Evangelos Denaxas, Fitchburg, MA (US)

(21) Appl. No.: 18/106,122

(22) Filed: Feb. 6, 2023

(30) Foreign Application Priority Data
Dec. 1, 2022 (GR) 20220100993

(51) Int. Cl. G06F 30/20; G06F 9/54

(52) U.S. Cl. CPC G06F 30/20; G06F 9/542; B60W 60/001

(57) ABSTRACT

Provided are methods, systems, and computer program products for defining and testing evolving event sequences. Some methods include specifying an event sequence tunnel in a scenario, wherein an entry space and an exit space of the event sequence tunnel are identified for a simulated agent. Dimensions of the event sequence tunnel are determined, and at least one factor is applied to dimensions of the event sequence tunnel at the entry space and propagated through the event sequence tunnel. The simulated agent is evaluated at the entry space until the exit space of the event sequence tunnel in a simulation. At least one consistent characteristic associated with the simulated agent is determined at the entry space, evolved, and replicated throughout respective event sequence tunnels. A response of an autonomous system to simulations of the scenario is evaluated in view of the at least one consistent characteristic of the simulated agent.

### CROSS-REFERENCE TO RELATED APPLICATIONS

This application claims priority to Greece Patent Application No. 20220100993, entitled “Defining and Testing Evolving Event Sequences,” filed on Dec. 1, 2022.

Autonomous systems obtain data from the surrounding environment and use the data to navigate through the environment. The autonomous systems include subsystems, sensors, and devices that process the data to enable the autonomous system to recognize and understand the environment. Based on the output of the subsystems, sensors, and devices, the autonomous systems make decisions to navigate through the environment.

### BRIEF DESCRIPTION OF THE FIGURES

FIG. 1 is an example environment in which a vehicle including one or more components of an autonomous system can be implemented;

FIG. 2 is a diagram of one or more systems of a vehicle included in an autonomous system;

FIG. 3 is a diagram of components of one or more devices and/or one or more systems of FIGS. 1 and 2;

FIG. 4 is a diagram of certain components of an autonomous system;

FIG. 5 is a diagram of an implementation of a process for defining and testing evolving event sequences;

FIG. 6 shows a testing infrastructure;

FIG. 7A shows a first scenario;

FIG. 7B shows a second scenario;

FIG. 8 shows a first flowchart of a process for defining and testing evolving event sequences; and

FIG. 9 shows a second flowchart of a process for defining and testing evolving event sequences.

### DETAILED DESCRIPTION

In the following description numerous specific details are set forth in order to provide a thorough understanding of the present disclosure for the purposes of explanation. It will be apparent, however, that the embodiments described by the present disclosure can be practiced without these specific details. In some instances, well-known structures and devices are illustrated in block diagram form in order to avoid unnecessarily obscuring aspects of the present disclosure.

Specific arrangements or orderings of schematic elements, such as those representing systems, devices, modules, instruction blocks, data elements, and/or the like are illustrated in the drawings for ease of description. However, it will be understood by those skilled in the art that the specific ordering or arrangement of the schematic elements in the drawings is not meant to imply that a particular order or sequence of processing, or separation of processes, is required unless explicitly described as such. Further, the inclusion of a schematic element in a drawing is not meant to imply that such element is required in all embodiments or that the features represented by such element may not be included in or combined with other elements in some embodiments unless explicitly described as such.

Further, where connecting elements such as solid or dashed lines or arrows are used in the drawings to illustrate a connection, relationship, or association between or among two or more other schematic elements, the absence of any such connecting elements is not meant to imply that no connection, relationship, or association can exist. In other words, some connections, relationships, or associations between elements are not illustrated in the drawings so as not to obscure the disclosure. In addition, for ease of illustration, a single connecting element can be used to represent multiple connections, relationships or associations between elements. For example, where a connecting element represents communication of signals, data, or instructions (e.g., “software instructions”), it should be understood by those skilled in the art that such element can represent one or multiple signal paths (e.g., a bus), as may be needed, to affect the communication.

Although the terms first, second, third, and/or the like are used to describe various elements, these elements should not be limited by these terms. The terms first, second, third, and/or the like are used only to distinguish one element from another. For example, a first contact could be termed a second contact and, similarly, a second contact could be termed a first contact without departing from the scope of the described embodiments. The first contact and the second contact are both contacts, but they are not the same contact.

The terminology used in the description of the various described embodiments herein is included for the purpose of describing particular embodiments only and is not intended to be limiting. As used in the description of the various described embodiments and the appended claims, the singular forms “a,” “an” and “the” are intended to include the plural forms as well and can be used interchangeably with “one or more” or “at least one,” unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this description specify the presence of stated features, integers, steps, operations, elements, and/or components, but do not preclude the presence or addition of one or more other features, integers, steps, operations, elements, components, and/or groups thereof.

As used herein, the terms “communication” and “communicate” refer to at least one of the reception, receipt, transmission, transfer, provision, and/or the like of information (or information represented by, for example, data, signals, messages, instructions, commands, and/or the like). For one unit (e.g., a device, a system, a component of a device or system, combinations thereof, and/or the like) to be in communication with another unit means that the one unit is able to directly or indirectly receive information from and/or send (e.g., transmit) information to the other unit. This may refer to a direct or indirect connection that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit (e.g., a third unit located between the first unit and the second unit) processes information received from the first unit and transmits the processed information to the second unit. In some embodiments, a message may refer to a network packet (e.g., a data packet and/or the like) that includes data.

As used herein, the term “if” is, optionally, construed to mean “when”, “upon”, “in response to determining,” “in response to detecting,” and/or the like, depending on the context. Similarly, the phrase “if it is determined” or “if [a stated condition or event] is detected” is, optionally, construed to mean “upon determining,” “in response to determining,” “upon detecting [the stated condition or event],” “in response to detecting [the stated condition or event],” and/or the like, depending on the context. Also, as used herein, the terms “has”, “have”, “having”, or the like are intended to be open-ended terms. Further, the phrase “based on” is intended to mean “based at least partially on” unless explicitly stated otherwise.

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments can be practiced without these specific details. In other instances, well-known methods, procedures, components, circuits, and networks have not been described in detail so as not to unnecessarily obscure aspects of the embodiments.

### General Overview

In some aspects and/or embodiments, systems, methods, and computer program products described herein include and/or implement evolving event sequences. A vehicle (such as an autonomous vehicle) includes multiple systems and devices that are used to navigate through the environment. The systems and devices are tested to ensure safe and reliable operation. In some embodiments, event sequences are defined and tested. Event sequence tunnels are specified for simulated agents in a scenario, wherein an entry space and an exit space of the event sequence tunnel are identified for each respective simulated agent. Waypoints or intermediate spaces are injected into the event sequence tunnel corresponding to the simulated agent. The simulated agents are evaluated at their respective entry space, waypoints, intermediate spaces, and exit space of the event sequence tunnel, wherein consistent characteristics are associated with the simulated agents. A response of an autonomous system (e.g., AV stack) in a simulation of a scenario is validated in view of consistent identification of the simulated agents in the scenario. In this manner, variability of characteristics associated with the simulated agents is removed.

By virtue of the implementation of systems, methods, and computer program products described herein, techniques for defining and testing evolving event sequences enables fast specification of a scenario to meet a predetermined test objective. Some of the advantages of these techniques include using consistent characteristics to test and validate AV behavior across many frames of data. The frames are not individually observed by a human observer to ensure consistent identification of respective simulated agents. Rather, the present techniques apply consistent values for the characteristics associated with the simulated agents at the entry space, exit space, and waypoints of the event sequence tunnel. Expensive, time-consuming frame-by-frame review of a sequence is avoided. The AV is tested automatically over larger slices of data without manually observing the simulation.

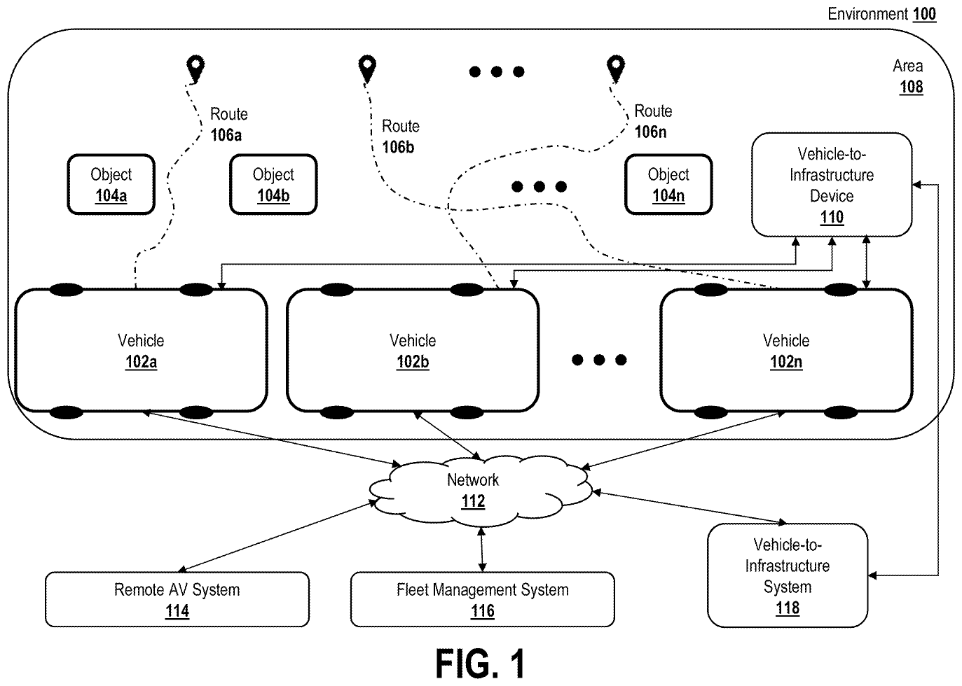

Referring now to FIG. 1, illustrated is example environment 100 in which vehicles that include autonomous systems, as well as vehicles that do not, are operated. As illustrated, environment 100 includes vehicles 102a-102n, objects 104a-104n, routes 106a-106n, area 108, vehicle-to-infrastructure (V2I) device 110, network 112, remote autonomous vehicle (AV) system 114, fleet management system 116, and V2I system 118. Vehicles 102a-102n, vehicle-to-infrastructure (V2I) device 110, network 112, autonomous vehicle (AV) system 114, fleet management system 116, and V2I system 118 interconnect (e.g., establish a connection to communicate and/or the like) via wired connections, wireless connections, or a combination of wired or wireless connections. In some embodiments, objects 104a-104n interconnect with at least one of vehicles 102a-102n, vehicle-to-infrastructure (V2I) device 110, network 112, autonomous vehicle (AV) system 114, fleet management system 116, and V2I system 118 via wired connections, wireless connections, or a combination of wired or wireless connections.

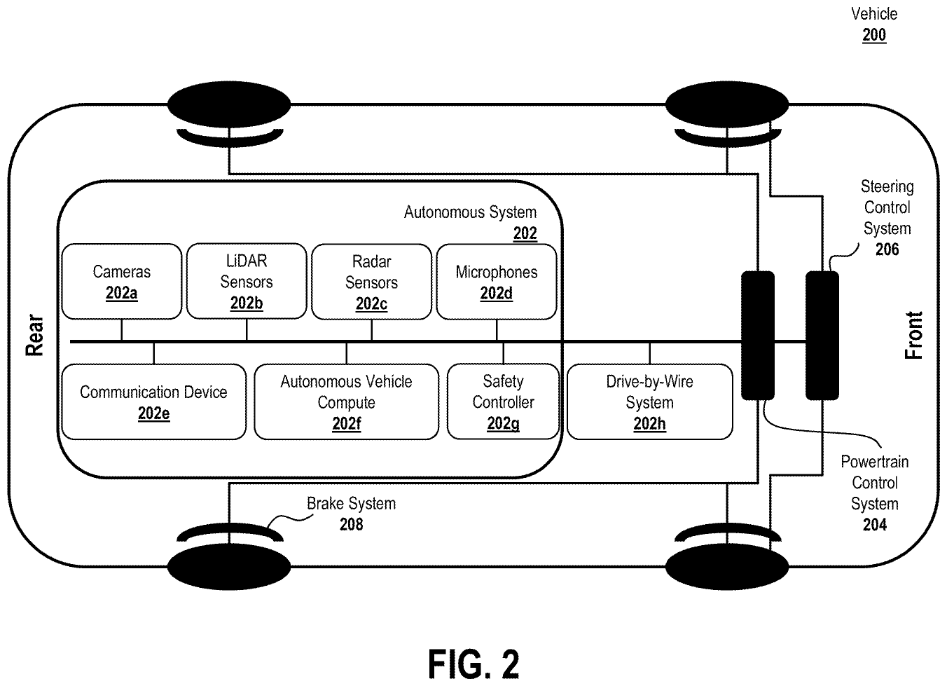

Vehicles 102a-102n (referred to individually as vehicle 102 and collectively as vehicles 102) include at least one device configured to transport goods and/or people. In some embodiments, vehicles 102 are configured to be in communication with V2I device 110, remote AV system 114, fleet management system 116, and/or V2I system 118 via network 112. In some embodiments, vehicles 102 include cars, buses, trucks, trains, and/or the like. In some embodiments, vehicles 102 are the same as, or similar to, vehicles 200, described herein (see FIG. 2). In some embodiments, a vehicle 200 of a set of vehicles 200 is associated with an autonomous fleet manager. In some embodiments, vehicles 102 travel along respective routes 106a-106n (referred to individually as route 106 and collectively as routes 106), as described herein. In some embodiments, one or more vehicles 102 include an autonomous system (e.g., an autonomous system that is the same as or similar to autonomous system 202).

Objects 104a-104n (referred to individually as object 104 and collectively as objects 104) include, for example, at least one vehicle, at least one pedestrian, at least one cyclist, at least one structure (e.g., a building, a sign, a fire hydrant, etc.), and/or the like. Each object 104 is stationary (e.g., located at a fixed location for a period of time) or mobile (e.g., having a velocity and associated with at least one trajectory). In some embodiments, objects 104 are associated with corresponding locations in area 108.

Routes 106a-106n (referred to individually as route 106 and collectively as routes 106) are each associated with (e.g., prescribe) a sequence of actions (also known as a trajectory) connecting states along which an AV can navigate. Each route 106 starts at an initial state (e.g., a state that corresponds to a first spatiotemporal location, velocity, and/or the like) and ends at a final goal state (e.g., a state that corresponds to a second spatiotemporal location that is different from the first spatiotemporal location) or goal region (e.g. a subspace of acceptable states (e.g., terminal states)). In some embodiments, the first state includes a location at which an individual or individuals are to be picked-up by the AV and the second state or region includes a location or locations at which the individual or individuals picked-up by the AV are to be dropped-off. In some embodiments, routes 106 include a plurality of acceptable state sequences (e.g., a plurality of spatiotemporal location sequences), the plurality of state sequences associated with (e.g., defining) a plurality of trajectories. In an example, routes 106 include only high level actions or imprecise state locations, such as a series of connected roads dictating turning directions at roadway intersections. Additionally, or alternatively, routes 106 may include more precise actions or states such as, for example, specific target lanes or precise locations within the lane areas and targeted speed at those positions. In an example, routes 106 include a plurality of precise state sequences along the at least one high level action sequence with a limited lookahead horizon to reach intermediate goals, where the combination of successive iterations of limited horizon state sequences cumulatively correspond to a plurality of trajectories that collectively form the high level route to terminate at the final goal state or region.

Area 108 includes a physical area (e.g., a geographic region) within which vehicles 102 can navigate. In an example, area 108 includes at least one state (e.g., a country, a province, an individual state of a plurality of states included in a country, etc.), at least one portion of a state, at least one city, at least one portion of a city, etc. In some embodiments, area 108 includes at least one named thoroughfare (referred to herein as a “road”) such as a highway, an interstate highway, a parkway, a city street, etc. Additionally, or alternatively, in some examples area 108 includes at least one unnamed road such as a driveway, a section of a parking lot, a section of a vacant and/or undeveloped lot, a dirt path, etc. In some embodiments, a road includes at least one lane (e.g., a portion of the road that can be traversed by vehicles 102). In an example, a road includes at least one lane associated with (e.g., identified based on) at least one lane marking.

Vehicle-to-Infrastructure (V2I) device 110 (sometimes referred to as a Vehicle-to-Infrastructure or Vehicle-to-Everything (V2X) device) includes at least one device configured to be in communication with vehicles 102 and/or V2I infrastructure system 118. In some embodiments, V2I device 110 is configured to be in communication with vehicles 102, remote AV system 114, fleet management system 116, and/or V2I system 118 via network 112. In some embodiments, V2I device 110 includes a radio frequency identification (RFID) device, signage, cameras (e.g., two-dimensional (2D) and/or three-dimensional (3D) cameras), lane markers, streetlights, parking meters, etc. In some embodiments, V2I device 110 is configured to communicate directly with vehicles 102. Additionally, or alternatively, in some embodiments V2I device 110 is configured to communicate with vehicles 102, remote AV system 114, and/or fleet management system 116 via V2I system 118. In some embodiments, V2I device 110 is configured to communicate with V2I system 118 via network 112.

Network 112 includes one or more wired and/or wireless networks. In an example, network 112 includes a cellular network (e.g., a long term evolution (LTE) network, a third generation (3G) network, a fourth generation (4G) network, a fifth generation (5G) network, a code division multiple access (CDMA) network, etc.), a public land mobile network (PLMN), a local area network (LAN), a wide area network (WAN), a metropolitan area network (MAN), a telephone network (e.g., the public switched telephone network (PSTN), a private network, an ad hoc network, an intranet, the Internet, a fiber optic-based network, a cloud computing network, etc., a combination of some or all of these networks, and/or the like.

Remote AV system 114 includes at least one device configured to be in communication with vehicles 102, V2I device 110, network 112, fleet management system 116, and/or V2I system 118 via network 112. In an example, remote AV system 114 includes a server, a group of servers, and/or other like devices. In some embodiments, remote AV system 114 is co-located with the fleet management system 116. In some embodiments, remote AV system 114 is involved in the installation of some or all of the components of a vehicle, including an autonomous system, an autonomous vehicle compute, software implemented by an autonomous vehicle compute, and/or the like. In some embodiments, remote AV system 114 maintains (e.g., updates and/or replaces) such components and/or software during the lifetime of the vehicle.

Fleet management system 116 includes at least one device configured to be in communication with vehicles 102, V2I device 110, remote AV system 114, and/or V2I infrastructure system 118. In an example, fleet management system 116 includes a server, a group of servers, and/or other like devices. In some embodiments, fleet management system 116 is associated with a ridesharing company (e.g., an organization that controls operation of multiple vehicles (e.g., vehicles that include autonomous systems and/or vehicles that do not include autonomous systems) and/or the like).

In some embodiments, V2I system 118 includes at least one device configured to be in communication with vehicles 102, V2I device 110, remote AV system 114, and/or fleet management system 116 via network 112. In some examples, V2I system 118 is configured to be in communication with V2I device 110 via a connection different from network 112. In some embodiments, V2I system 118 includes a server, a group of servers, and/or other like devices. In some embodiments, V2I system 118 is associated with a municipality or a private institution (e.g., a private institution that maintains V2I device 110 and/or the like).

The number and arrangement of elements illustrated in FIG. 1 are provided as an example. There can be additional elements, fewer elements, different elements, and/or differently arranged elements, than those illustrated in FIG. 1. Additionally, or alternatively, at least one element of environment 100 can perform one or more functions described as being performed by at least one different element of FIG. 1. Additionally, or alternatively, at least one set of elements of environment 100 can perform one or more functions described as being performed by at least one different set of elements of environment 100.

Referring now to FIG. 2, vehicle 200 (which may be the same as, or similar to vehicles 102 of FIG. 1) includes or is associated with autonomous system 202, powertrain control system 204, steering control system 206, and brake system 208. In some embodiments, vehicle 200 is the same as or similar to vehicle 102 (see FIG. 1). In some embodiments, autonomous system 202 is configured to confer vehicle 200 autonomous driving capability (e.g., implement at least one driving automation or maneuver-based function, feature, device, and/or the like that enable vehicle 200 to be partially or fully operated without human intervention including, without limitation, fully autonomous vehicles (e.g., vehicles that forego reliance on human intervention such as Level 5 ADS-operated vehicles), highly autonomous vehicles (e.g., vehicles that forego reliance on human intervention in certain situations such as Level 4 ADS-operated vehicles), conditional autonomous vehicles (e.g., vehicles that forego reliance on human intervention in limited situations such as Level 3 ADS-operated vehicles) and/or the like. In one embodiment, autonomous system 202 includes operational or tactical functionality required to operate vehicle 200 in on-road traffic and perform part or all of Dynamic Driving Task (DDT) on a sustained basis. In another embodiment, autonomous system 202 includes an Advanced Driver Assistance System (ADAS) that includes driver support features. Autonomous system 202 supports various levels of driving automation, ranging from no driving automation (e.g., Level 0) to full driving automation (e.g., Level 5). For a detailed description of fully autonomous vehicles and highly autonomous vehicles, reference may be made to SAE International's standard J3016: Taxonomy and Definitions for Terms Related to On-Road Motor Vehicle Automated Driving Systems, which is incorporated by reference in its entirety. In some embodiments, vehicle 200 is associated with an autonomous fleet manager and/or a ridesharing company.

Autonomous system 202 includes a sensor suite that includes one or more devices such as cameras 202a, LiDAR sensors 202b, radar sensors 202c, and microphones 202d. In some embodiments, autonomous system 202 can include more or fewer devices and/or different devices (e.g., ultrasonic sensors, inertial sensors, GPS receivers (discussed below), odometry sensors that generate data associated with an indication of a distance that vehicle 200 has traveled, and/or the like). In some embodiments, autonomous system 202 uses the one or more devices included in autonomous system 202 to generate data associated with environment 100, described herein. The data generated by the one or more devices of autonomous system 202 can be used by one or more systems described herein to observe the environment (e.g., environment 100) in which vehicle 200 is located. In some embodiments, autonomous system 202 includes communication device 202e, autonomous vehicle compute 202f, drive-by-wire (DBW) system 202h, and safety controller 202g.

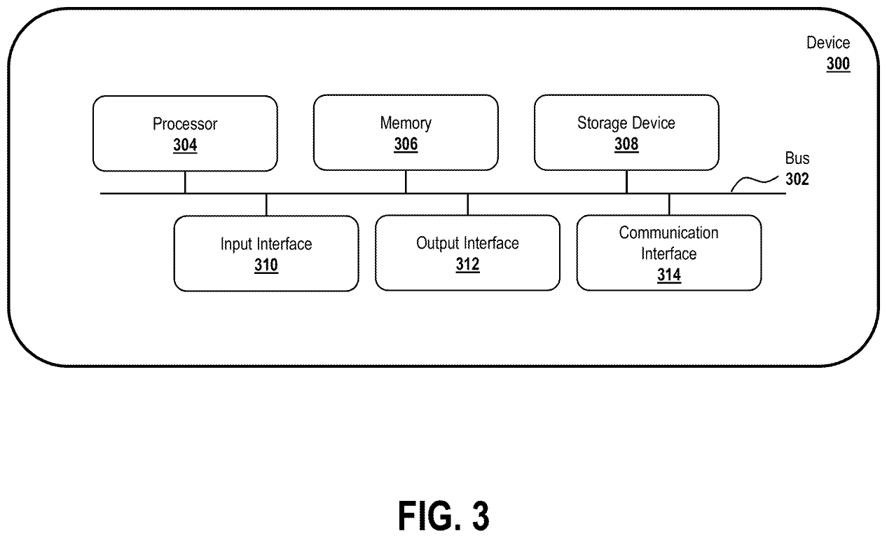

Cameras 202a include at least one device configured to be in communication with communication device 202e, autonomous vehicle compute 202f, and/or safety controller 202g via a bus (e.g., a bus that is the same as or similar to bus 302 of FIG. 3). Cameras 202a include at least one camera (e.g., a digital camera using a light sensor such as a Charge-Coupled Device (CCD), a thermal camera, an infrared (IR) camera, an event camera, and/or the like) to capture images including physical objects (e.g., cars, buses, curbs, people, and/or the like). In some embodiments, camera 202a generates camera data as output. In some examples, camera 202a generates camera data that includes image data associated with an image. In this example, the image data may specify at least one parameter (e.g., image characteristics such as exposure, brightness, etc., an image timestamp, and/or the like) corresponding to the image. In such an example, the image may be in a format (e.g., RAW, JPEG, PNG, and/or the like). In some embodiments, camera 202a includes a plurality of independent cameras configured on (e.g., positioned on) a vehicle to capture images for the purpose of stereopsis (stereo vision). In some examples, camera 202a includes a plurality of cameras that generate image data and transmit the image data to autonomous vehicle compute 202f and/or a fleet management system (e.g., a fleet management system that is the same as or similar to fleet management system 116 of FIG. 1). In such an example, autonomous vehicle compute 202f determines depth to one or more objects in a field of view of at least two cameras of the plurality of cameras based on the image data from the at least two cameras. In some embodiments, cameras 202a is configured to capture images of objects within a distance from cameras 202a (e.g., up to 100 meters, up to a kilometer, and/or the like). Accordingly, cameras 202a include features such as sensors and lenses that are optimized for perceiving objects that are at one or more distances from cameras 202a.

In an embodiment, camera 202a includes at least one camera configured to capture one or more images associated with one or more traffic lights, street signs and/or other physical objects that provide visual navigation information. In some embodiments, camera 202a generates traffic light data associated with one or more images. In some examples, camera 202a generates TLD (Traffic Light Detection) data associated with one or more images that include a format (e.g., RAW, JPEG, PNG, and/or the like). In some embodiments, camera 202a that generates TLD data differs from other systems described herein incorporating cameras in that camera 202a can include one or more cameras with a wide field of view (e.g., a wide-angle lens, a fish-eye lens, a lens having a viewing angle of approximately 120 degrees or more, and/or the like) to generate images about as many physical objects as possible.

Light Detection and Ranging (LiDAR) sensors 202b include at least one device configured to be in communication with communication device 202e, autonomous vehicle compute 202f, and/or safety controller 202g via a bus (e.g., a bus that is the same as or similar to bus 302 of FIG. 3). LiDAR sensors 202b include a system configured to transmit light from a light emitter (e.g., a laser transmitter). Light emitted by LiDAR sensors 202b include light (e.g., infrared light and/or the like) that is outside of the visible spectrum. In some embodiments, during operation, light emitted by LiDAR sensors 202b encounters a physical object (e.g., a vehicle) and is reflected back to LiDAR sensors 202b. In some embodiments, the light emitted by LiDAR sensors 202b does not penetrate the physical objects that the light encounters. LiDAR sensors 202b also include at least one light detector which detects the light that was emitted from the light emitter after the light encounters a physical object. In some embodiments, at least one data processing system associated with LiDAR sensors 202b generates an image (e.g., a point cloud, a combined point cloud, and/or the like) representing the objects included in a field of view of LiDAR sensors 202b. In some examples, the at least one data processing system associated with LiDAR sensor 202b generates an image that represents the boundaries of a physical object, the surfaces (e.g., the topology of the surfaces) of the physical object, and/or the like. In such an example, the image is used to determine the boundaries of physical objects in the field of view of LiDAR sensors 202b.

Radio Detection and Ranging (radar) sensors 202c include at least one device configured to be in communication with communication device 202e, autonomous vehicle compute 202f, and/or safety controller 202g via a bus (e.g., a bus that is the same as or similar to bus 302 of FIG. 3). Radar sensors 202c include a system configured to transmit radio waves (either pulsed or continuously). The radio waves transmitted by radar sensors 202c include radio waves that are within a predetermined spectrum. In some embodiments, during operation, radio waves transmitted by radar sensors 202c encounter a physical object and are reflected back to radar sensors 202c. In some embodiments, the radio waves transmitted by radar sensors 202c are not reflected by some objects. In some embodiments, at least one data processing system associated with radar sensors 202c generates signals representing the objects included in a field of view of radar sensors 202c. For example, the at least one data processing system associated with radar sensor 202c generates an image that represents the boundaries of a physical object, the surfaces (e.g., the topology of the surfaces) of the physical object, and/or the like. In some examples, the image is used to determine the boundaries of physical objects in the field of view of radar sensors 202c.

Microphones 202d includes at least one device configured to be in communication with communication device 202e, autonomous vehicle compute 202f, and/or safety controller 202g via a bus (e.g., a bus that is the same as or similar to bus 302 of FIG. 3). Microphones 202d include one or more microphones (e.g., array microphones, external microphones, and/or the like) that capture audio signals and generate data associated with (e.g., representing) the audio signals. In some examples, microphones 202d include transducer devices and/or like devices. In some embodiments, one or more systems described herein can receive the data generated by microphones 202d and determine a position of an object relative to vehicle 200 (e.g., a distance and/or the like) based on the audio signals associated with the data.

Communication device 202e includes at least one device configured to be in communication with cameras 202a, LiDAR sensors 202b, radar sensors 202c, microphones 202d, autonomous vehicle compute 202f, safety controller 202g, and/or DBW (Drive-By-Wire) system 202h. For example, communication device 202e may include a device that is the same as or similar to communication interface 314 of FIG. 3. In some embodiments, communication device 202e includes a vehicle-to-vehicle (V2V) communication device (e.g., a device that enables wireless communication of data between vehicles).

Autonomous vehicle compute 202f include at least one device configured to be in communication with cameras 202a, LiDAR sensors 202b, radar sensors 202c, microphones 202d, communication device 202e, safety controller 202g, and/or DBW system 202h. In some examples, autonomous vehicle compute 202f includes a device such as a client device, a mobile device (e.g., a cellular telephone, a tablet, and/or the like), a server (e.g., a computing device including one or more central processing units, graphical processing units, and/or the like), and/or the like. In some embodiments, autonomous vehicle compute 202f is the same as or similar to autonomous vehicle compute 400, described herein. Additionally, or alternatively, in some embodiments autonomous vehicle compute 202f is configured to be in communication with an autonomous vehicle system (e.g., an autonomous vehicle system that is the same as or similar to remote AV system 114 of FIG. 1), a fleet management system (e.g., a fleet management system that is the same as or similar to fleet management system 116 of FIG. 1), a V2I device (e.g., a V2I device that is the same as or similar to V2I device 110 of FIG. 1), and/or a V2I system (e.g., a V2I system that is the same as or similar to V2I system 118 of FIG. 1).

Safety controller 202g includes at least one device configured to be in communication with cameras 202a, LiDAR sensors 202b, radar sensors 202c, microphones 202d, communication device 202e, autonomous vehicle computer 202f, and/or DBW system 202h. In some examples, safety controller 202g includes one or more controllers (electrical controllers, electromechanical controllers, and/or the like) that are configured to generate and/or transmit control signals to operate one or more devices of vehicle 200 (e.g., powertrain control system 204, steering control system 206, brake system 208, and/or the like). In some embodiments, safety controller 202g is configured to generate control signals that take precedence over (e.g., overrides) control signals generated and/or transmitted by autonomous vehicle compute 202f.

DBW system 202h includes at least one device configured to be in communication with communication device 202e and/or autonomous vehicle compute 202f. In some examples, DBW system 202h includes one or more controllers (e.g., electrical controllers, electromechanical controllers, and/or the like) that are configured to generate and/or transmit control signals to operate one or more devices of vehicle 200 (e.g., powertrain control system 204, steering control system 206, brake system 208, and/or the like). Additionally, or alternatively, the one or more controllers of DBW system 202h are configured to generate and/or transmit control signals to operate at least one different device (e.g., a turn signal, headlights, door locks, windshield wipers, and/or the like) of vehicle 200.

Powertrain control system 204 includes at least one device configured to be in communication with DBW system 202h. In some examples, powertrain control system 204 includes at least one controller, actuator, and/or the like. In some embodiments, powertrain control system 204 receives control signals from DBW system 202h and powertrain control system 204 causes vehicle 200 to make longitudinal vehicle motion, such as start moving forward, stop moving forward, start moving backward, stop moving backward, accelerate in a direction, decelerate in a direction or to make lateral vehicle motion such as performing a left turn, performing a right turn, and/or the like. In an example, powertrain control system 204 causes the energy (e.g., fuel, electricity, and/or the like) provided to a motor of the vehicle to increase, remain the same, or decrease, thereby causing at least one wheel of vehicle 200 to rotate or not rotate.

Steering control system 206 includes at least one device configured to rotate one or more wheels of vehicle 200. In some examples, steering control system 206 includes at least one controller, actuator, and/or the like. In some embodiments, steering control system 206 causes the front two wheels and/or the rear two wheels of vehicle 200 to rotate to the left or right to cause vehicle 200 to turn to the left or right. In other words, steering control system 206 causes activities necessary for the regulation of the y-axis component of vehicle motion.

Brake system 208 includes at least one device configured to actuate one or more brakes to cause vehicle 200 to reduce speed and/or remain stationary. In some examples, brake system 208 includes at least one controller and/or actuator that is configured to cause one or more calipers associated with one or more wheels of vehicle 200 to close on a corresponding rotor of vehicle 200. Additionally, or alternatively, in some examples brake system 208 includes an automatic emergency braking (AEB) system, a regenerative braking system, and/or the like.

In some embodiments, vehicle 200 includes at least one platform sensor (not explicitly illustrated) that measures or infers properties of a state or a condition of vehicle 200. In some examples, vehicle 200 includes platform sensors such as a global positioning system (GPS) receiver, an inertial measurement unit (IMU), a wheel speed sensor, a wheel brake pressure sensor, a wheel torque sensor, an engine torque sensor, a steering angle sensor, and/or the like. Although brake system 208 is illustrated to be located in the near side of vehicle 200 in FIG. 2, brake system 208 may be located anywhere in vehicle 200.

Referring now to FIG. 3, illustrated is a schematic diagram of a device 300. As illustrated, device 300 includes processor 304, memory 306, storage component 308, input interface 310, output interface 312, communication interface 314, and bus 302. In some embodiments, device 300 corresponds to at least one device of vehicles 102 (e.g., at least one device of a system of vehicles 102) and/or one or more devices of network 112 (e.g., one or more devices of a system of network 112). In some embodiments, one or more devices of vehicles 102 (e.g., one or more devices of a system of vehicles 102) and/or one or more devices of network 112 (e.g., one or more devices of a system of network 112) include at least one device 300 and/or at least one component of device 300. As shown in FIG. 3, device 300 includes bus 302, processor 304, memory 306, storage component 308, input interface 310, output interface 312, and communication interface 314.

Bus 302 includes a component that permits communication among the components of device 300. In some cases, processor 304 includes a processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 306 includes random access memory (RAM), read-only memory (ROM), and/or another type of dynamic and/or static storage device (e.g., flash memory, magnetic memory, optical memory, and/or the like) that stores data and/or instructions for use by processor 304.

Storage component 308 stores data and/or software related to the operation and use of device 300. In some examples, storage component 308 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 310 includes a component that permits device 300 to receive information, such as via user input (e.g., a touchscreen display, a keyboard, a keypad, a mouse, a button, a switch, a microphone, a camera, and/or the like). Additionally or alternatively, in some embodiments input interface 310 includes a sensor that senses information (e.g., a global positioning system (GPS) receiver, an accelerometer, a gyroscope, an actuator, and/or the like). Output interface 312 includes a component that provides output information from device 300 (e.g., a display, a speaker, one or more light-emitting diodes (LEDs), and/or the like).

In some embodiments, communication interface 314 includes a transceiver-like component (e.g., a transceiver, a separate receiver and transmitter, and/or the like) that permits device 300 to communicate with other devices via a wired connection, a wireless connection, or a combination of wired and wireless connections. In some examples, communication interface 314 permits device 300 to receive information from another device and/or provide information to another device. In some examples, communication interface 314 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, device 300 performs one or more processes described herein. Device 300 performs these processes based on processor 304 executing software instructions stored by a computer-readable medium, such as memory 305 and/or storage component 308. A computer-readable medium (e.g., a non-transitory computer readable medium) is defined herein as a non-transitory memory device. A non-transitory memory device includes memory space located inside a single physical storage device or memory space spread across multiple physical storage devices.

In some embodiments, software instructions are read into memory 306 and/or storage component 308 from another computer-readable medium or from another device via communication interface 314. When executed, software instructions stored in memory 306 and/or storage component 308 cause processor 304 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 306 and/or storage component 308 includes data storage or at least one data structure (e.g., a database and/or the like). Device 300 is capable of receiving information from, storing information in, communicating information to, or searching information stored in the data storage or the at least one data structure in memory 306 or storage component 308. In some examples, the information includes network data, input data, output data, or any combination thereof.

In some embodiments, device 300 is configured to execute software instructions that are either stored in memory 306 and/or in the memory of another device (e.g., another device that is the same as or similar to device 300). As used herein, the term “module” refers to at least one instruction stored in memory 306 and/or in the memory of another device that, when executed by processor 304 and/or by a processor of another device (e.g., another device that is the same as or similar to device 300) cause device 300 (e.g., at least one component of device 300) to perform one or more processes described herein. In some embodiments, a module is implemented in software, firmware, hardware, and/or the like.

The number and arrangement of components illustrated in FIG. 3 are provided as an example. In some embodiments, device 300 can include additional components, fewer components, different components, or differently arranged components than those illustrated in FIG. 3. Additionally or alternatively, a set of components (e.g., one or more components) of device 300 can perform one or more functions described as being performed by another component or another set of components of device 300.

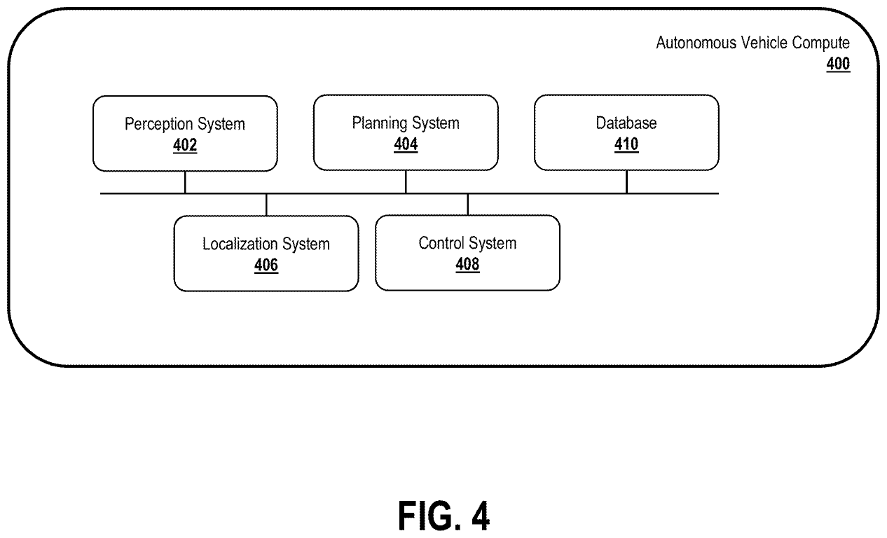

Referring now to FIG. 4, illustrated is an example block diagram of an autonomous vehicle compute 400 (sometimes referred to as an “AV stack”). As illustrated, autonomous vehicle compute 400 includes perception system 402 (sometimes referred to as a perception module), planning system 404 (sometimes referred to as a planning module), localization system 406 (sometimes referred to as a localization module), control system 408 (sometimes referred to as a control module), and database 410. In some embodiments, perception system 402, planning system 404, localization system 406, control system 408, and database 410 are included and/or implemented in an autonomous navigation system of a vehicle (e.g., autonomous vehicle compute 202f of vehicle 200). Additionally, or alternatively, in some embodiments perception system 402, planning system 404, localization system 406, control system 408, and database 410 are included in one or more standalone systems (e.g., one or more systems that are the same as or similar to autonomous vehicle compute 400 and/or the like). In some examples, perception system 402, planning system 404, localization system 406, control system 408, and database 410 are included in one or more standalone systems that are located in a vehicle and/or at least one remote system as described herein. In some embodiments, any and/or all of the systems included in autonomous vehicle compute 400 are implemented in software (e.g., in software instructions stored in memory), computer hardware (e.g., by microprocessors, microcontrollers, application-specific integrated circuits (ASICs), Field Programmable Gate Arrays (FPGAs), and/or the like), or combinations of computer software and computer hardware. It will also be understood that, in some embodiments, autonomous vehicle compute 400 is configured to be in communication with a remote system (e.g., an autonomous vehicle system that is the same as or similar to remote AV system 114, a fleet management system 116 that is the same as or similar to fleet management system 116, a V2I system that is the same as or similar to V2I system 118, and/or the like).

In some embodiments, perception system 402 receives data associated with at least one physical object (e.g., data that is used by perception system 402 to detect the at least one physical object) in an environment and classifies the at least one physical object. In some examples, perception system 402 receives image data captured by at least one camera (e.g., cameras 202a), the image associated with (e.g., representing) one or more physical objects within a field of view of the at least one camera. In such an example, perception system 402 classifies at least one physical object based on one or more groupings of physical objects (e.g., bicycles, vehicles, traffic signs, pedestrians, and/or the like). In some embodiments, perception system 402 transmits data associated with the classification of the physical objects to planning system 404 based on perception system 402 classifying the physical objects.

In some embodiments, planning system 404 receives data associated with a destination and generates data associated with at least one route (e.g., routes 106) along which a vehicle (e.g., vehicles 102) can travel along toward a destination. In some embodiments, planning system 404 periodically or continuously receives data from perception system 402 (e.g., data associated with the classification of physical objects, described above) and planning system 404 updates the at least one trajectory or generates at least one different trajectory based on the data generated by perception system 402. In other words, planning system 404 may perform tactical function-related tasks that are required to operate vehicle 102 in on-road traffic. Tactical efforts involve maneuvering the vehicle in traffic during a trip, including but not limited to deciding whether and when to overtake another vehicle, change lanes, or selecting an appropriate speed, acceleration, deceleration, etc. In some embodiments, planning system 404 receives data associated with an updated position of a vehicle (e.g., vehicles 102) from localization system 406 and planning system 404 updates the at least one trajectory or generates at least one different trajectory based on the data generated by localization system 406.

In some embodiments, localization system 406 receives data associated with (e.g., representing) a location of a vehicle (e.g., vehicles 102) in an area. In some examples, localization system 406 receives LiDAR data associated with at least one point cloud generated by at least one LiDAR sensor (e.g., LiDAR sensors 202b). In certain examples, localization system 406 receives data associated with at least one point cloud from multiple LiDAR sensors and localization system 406 generates a combined point cloud based on each of the point clouds. In these examples, localization system 406 compares the at least one point cloud or the combined point cloud to two-dimensional (2D) and/or a three-dimensional (3D) map of the area stored in database 410. Localization system 406 then determines the position of the vehicle in the area based on localization system 406 comparing the at least one point cloud or the combined point cloud to the map. In some embodiments, the map includes a combined point cloud of the area generated prior to navigation of the vehicle. In some embodiments, maps include, without limitation, high-precision maps of the roadway geometric properties, maps describing road network connectivity properties, maps describing roadway physical properties (such as traffic speed, traffic volume, the number of vehicular and cyclist traffic lanes, lane width, lane traffic directions, or lane marker types and locations, or combinations thereof), and maps describing the spatial locations of road features such as crosswalks, traffic signs or other travel signals of various types. In some embodiments, the map is generated in real-time based on the data received by the perception system.

In another example, localization system 406 receives Global Navigation Satellite System (GNSS) data generated by a global positioning system (GPS) receiver. In some examples, localization system 406 receives GNSS data associated with the location of the vehicle in the area and localization system 406 determines a latitude and longitude of the vehicle in the area. In such an example, localization system 406 determines the position of the vehicle in the area based on the latitude and longitude of the vehicle. In some embodiments, localization system 406 generates data associated with the position of the vehicle. In some examples, localization system 406 generates data associated with the position of the vehicle based on localization system 406 determining the position of the vehicle. In such an example, the data associated with the position of the vehicle includes data associated with one or more semantic properties corresponding to the position of the vehicle.

In some embodiments, control system 408 receives data associated with at least one trajectory from planning system 404 and control system 408 controls operation of the vehicle. In some examples, control system 408 receives data associated with at least one trajectory from planning system 404 and control system 408 controls operation of the vehicle by generating and transmitting control signals to cause a powertrain control system (e.g., DBW system 202h, powertrain control system 204, and/or the like), a steering control system (e.g., steering control system 206), and/or a brake system (e.g., brake system 208) to operate. For example, control system 408 is configured to perform operational functions such as a lateral vehicle motion control or a longitudinal vehicle motion control. The lateral vehicle motion control causes activities necessary for the regulation of the y-axis component of vehicle motion. The longitudinal vehicle motion control causes activities necessary for the regulation of the x-axis component of vehicle motion. In an example, where a trajectory includes a left turn, control system 408 transmits a control signal to cause steering control system 206 to adjust a steering angle of vehicle 200, thereby causing vehicle 200 to turn left. Additionally, or alternatively, control system 408 generates and transmits control signals to cause other devices (e.g., headlights, turn signal, door locks, windshield wipers, and/or the like) of vehicle 200 to change states.

In some embodiments, perception system 402, planning system 404, localization system 406, and/or control system 408 implement at least one machine learning model (e.g., at least one multilayer perceptron (MLP), at least one convolutional neural network (CNN), at least one recurrent neural network (RNN), at least one autoencoder, at least one transformer, and/or the like). In some examples, perception system 402, planning system 404, localization system 406, and/or control system 408 implement at least one machine learning model alone or in combination with one or more of the above-noted systems. In some examples, perception system 402, planning system 404, localization system 406, and/or control system 408 implement at least one machine learning model as part of a pipeline (e.g., a pipeline for identifying one or more objects located in an environment and/or the like).

Database 410 stores data that is transmitted to, received from, and/or updated by perception system 402, planning system 404, localization system 406 and/or control system 408. In some examples, database 410 includes a storage component (e.g., a storage component that is the same as or similar to storage component 308 of FIG. 3) that stores data and/or software related to the operation and uses at least one system of autonomous vehicle compute 400. In some embodiments, database 410 stores data associated with 2D and/or 3D maps of at least one area. In some examples, database 410 stores data associated with 2D and/or 3D maps of a portion of a city, multiple portions of multiple cities, multiple cities, a county, a state, a State (e.g., a country), and/or the like). In such an example, a vehicle (e.g., a vehicle that is the same as or similar to vehicles 102 and/or vehicle 200) can drive along one or more drivable regions (e.g., single-lane roads, multi-lane roads, highways, back roads, off road trails, and/or the like) and cause at least one LiDAR sensor (e.g., a LIDAR sensor that is the same as or similar to LiDAR sensors 202b) to generate data associated with an image representing the objects included in a field of view of the at least one LiDAR sensor.

In some embodiments, database 410 can be implemented across a plurality of devices. In some examples, database 410 is included in a vehicle (e.g., a vehicle that is the same as or similar to vehicles 102 and/or vehicle 200), an autonomous vehicle system (e.g., an autonomous vehicle system that is the same as or similar to remote AV system 114, a fleet management system (e.g., a fleet management system that is the same as or similar to fleet management system 116 of FIG. 1, a V2I system (e.g., a V2I system that is the same as or similar to V2I system 118 of FIG. 1) and/or the like.

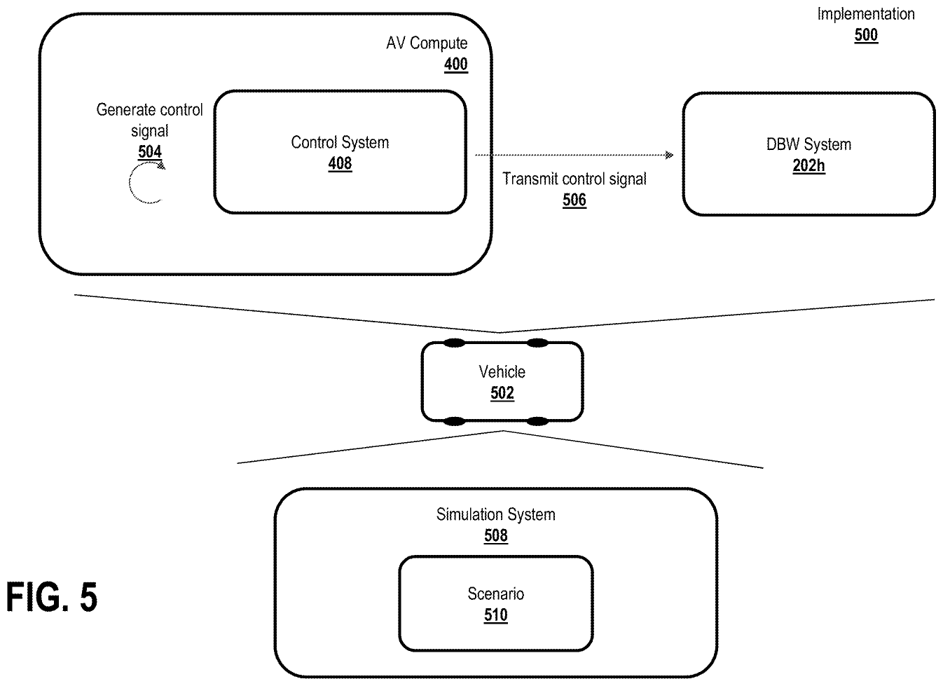

Referring now to FIG. 5, illustrated is a diagram of an implementation 500 of a process for defining and testing evolving event sequences. In some embodiments, implementation 500 includes a vehicle 502 with an AV compute 400 and DBW system 202h. In some embodiments, AV compute 400 is the same as or similar to AV compute 400 of FIG. 4, the control system 408 is the same as or similar to the control system 408 of FIG. 4, and DBW system 202h is the same as or similar to DBW system 202h of FIG. 2. The vehicle 502 includes autonomous systems, such as the AV compute 400 that generates control signals (504). A control system 408 controls operation of the vehicle by generating and transmitting control signals (506) to cause a DBW system 202h to operate.

In the example of FIG. 5, inputs to the AV compute 400 are simulated in scenarios 510 generated by a simulation system 508, and the outputs (e.g., control signal 506) of the AV compute 400 are obtained to evaluate the performance of the AV compute 400. In some embodiments, outputs obtained to evaluate performance of the AV include, for example, data output by subsystems (e.g., perception system 402, planning system 404, localization system 406, control system 408, and database 410 of FIG. 4), sensors (cameras 202a, LiDAR sensors 202b, radar sensors 202c, microphones 202d of FIG. 2), and devices (e.g., communication device 202e, safety controller 202g, and/or DBW system 202h of FIG. 2) that process the data to enable an autonomous vehicle to recognize, understand, and make decisions within the environment.

A scenario of scenarios 510 includes time series data that is representative of a simulated environment. In examples, a simulation imitates a real-world environment by inputting the time series data representing the environment into an autonomous system. In examples, hardware of the autonomous system, software of the autonomous system, or any combinations thereof receive the time series data, and generate outputs in response to the inputs. The time series data includes, for example, sensor data (e.g., data representing point clouds, optical camera images, infrared camera images, radar images, and/or the like collected at one or more points in time), vehicle dynamics, agent models, data corresponding to environmental conditions, and the like. Additionally, in examples, the time series data includes perception data, sensor data, vehicle dynamics, environmental data, and the like. The time series data is collectively referred to as a scenario, and the scenario is input to the autonomous system. The simulation system 508 obtains output from the autonomous system, wherein the output represents the behavior or response of the autonomous system to the scenario. The simulation system dynamically and iteratively updates the scenario according to the response of the autonomous system. In examples, the scenario is referred to as including frames of data, where a frame is a set of time series data at a specified point in time. The scenario is simulated by generating frames of data that are input to the autonomous system, and the response (e.g., outputs) of the autonomous system to scenario informs subsequent frames of data for an interval of time. In some embodiments, events are specified in the scenario and used to test, validate, or verify functionality of the autonomous system. In examples, an event refers to a thing that happens or occurrence during a simulation. An event may be, for example, a detected object or agent. In some embodiments, events correspond to a configuration of one or more parameters observed by the system under test. The one or more parameters are observed by the system under test and used to generate an output (e.g., behavior or response) of the autonomous system. In examples, expected parameters are associated with elements of the scenario.

In the example of FIG. 5, the autonomous system is the AV compute 400 that enables perception of the environment, including but not limited to object detection. The objects are, for example, objects 104a-104n of FIG. 1 and include, for example, at least one vehicle, at least one pedestrian, at least one cyclist, at least one structure (e.g., a building, a sign, a fire hydrant, etc.), and/or the like. The present techniques enable simulations of scenarios that include one or more agents. In examples, an agent is an object capable of motion, such as a vehicle, pedestrian, cyclist, and the like. Other moving objects can also be identified as an agent, such as a tumbling garbage bin, a plastic bag blowing in the wind, and the like. Additionally, some objects are erroneously identified as an agent, such as a road block not capable of motion. The navigation of the autonomous vehicle in the simulated environment is based on, at least in part, predicted motion of the detected agents. The autonomous vehicle 502 is tested to ensure proper operation of the systems and sensors that enable navigation of the AV.

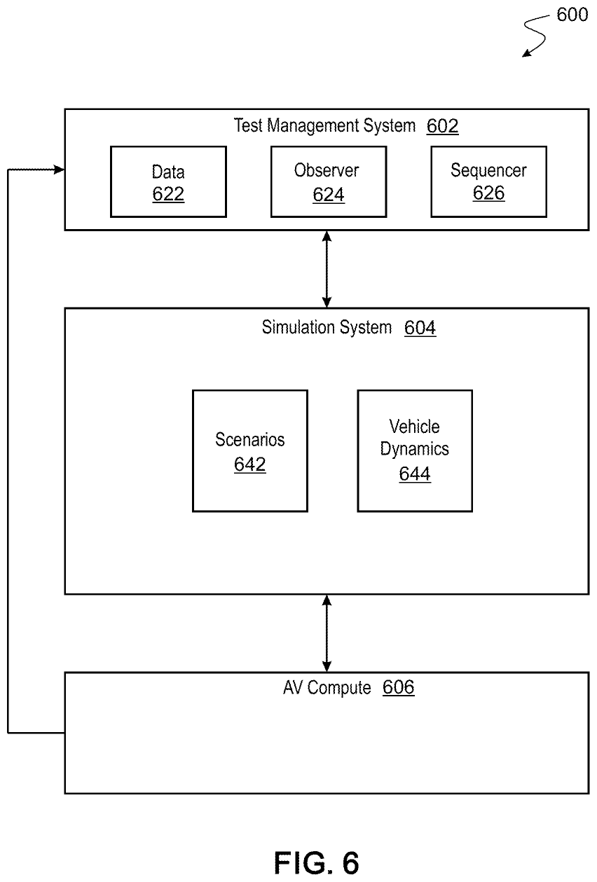

In examples, the simulated environment is based on real world data. For example, a scenario is based on real world drive logs as described with respect to FIG. 6. The real world drive logs include agent trajectories (e.g., trajectories representing an agent's movement in the environment over a period of time) and other characteristics as captured by vehicles, systems, sensors, or devices in the real world. In examples, a scenario is artificially constructed using objects and agents extracted from real world data. Scenarios are replicated during simulation by spawning simulated agents based on characteristics of agents detected in the real world drive logs. In some simulations, the simulated agent characteristics extracted from the real world data are inconsistent across frames of the scenario. Simulated agent characteristics extracted from the real world data are based on data captured by vehicles, systems, sensors, or devices in the real world. The characteristics in the data captured by vehicles, systems, sensors, or devices in the real world varies according to the particular hardware or software used to capture the real world data.

The present techniques enable the automatic creation of scenarios with consistent characteristics. In some embodiments, a simulated agent is specified in a scenario according to one or more characteristics at multiple timestamps. Characteristics of a scenario represent inputs to the system under test during a simulation. In examples, characteristics of a scenario represent a ground truth of time-series data in the simulation. The system under test observes the characteristics of the scenario, and outputs its own observed characteristics. A comparison of the characteristics of a scenario and the observed characteristics output by the system under test is used to test, validate, or verify some functionality of the system under test.

In examples, the at least one characteristic of a simulated agent is observed by the autonomous system at a first timestamp during a simulation of a scenario. The simulated agent is specified in subsequent timestamps according to the at least one characteristic. In some embodiments, the first timestamp and subsequent timestamps are predefined frames of the scenario. The present techniques replicate the observed characteristic output by the system under test to determine an accuracy of the AV in capturing the characteristic.

For example, in a drive log, as an agent disappears and reappears from the view of the AV, perception (e.g., perception system 402 of FIG. 4) can identify the agent as a new or different agent when compared to the first identification of the agent. The identification associated with an agent is a characteristic. Misidentifying or re-identifying an agent being tracked results in inconsistent characteristics associated with the agent as simulated in a scenario based on the drive log. A simulation that executes this scenario is unable to evaluate an AV response to consistent agent identification across frames of the scenario. The present techniques enable consistent characteristics associated with simulated agents in a scenario. The consistent characteristics are determined from observed characteristics in the scenario. At least one expected parameter is applied to the simulated agent at subsequent timestamps of the scenario. The expected parameter represents associations between characteristics at timestamps of the scenario. A characteristic that is consistent evolves according to the expected parameter during a simulation. In examples, simulations of a scenario are iteratively executed to evaluate a system under test. For example, in each execution of a scenario the system under test captures the at least one characteristic at a first timestamp, and the simulated agent is specified at subsequent timestamps according to the respective at least one characteristic. The response of the system under to consistent characteristics in respective simulations enables a comparison of responses, where deviations between the responses can indicate a fault, error, or failure of the system under test.

FIG. 6 shows a testing infrastructure 600. The testing infrastructure 600 enables consistent simulated agent characteristics across frames of a simulation. The testing infrastructure 600 is implemented at, for example, a device 300 of FIG. 3. The testing infrastructure 600 enables testing, validation, and verification of autonomous systems. For ease of description, the present techniques are described using an autonomous vehicle as the autonomous system. However, any autonomous system can be tested according to the present techniques. In examples, testing ensures that autonomous vehicles operate in a safe and error-free manner.

The testing infrastructure 600 includes a test management system 602, simulation system 604, and AV compute 606. The test management system 602 and simulation system 604 are shown as separate systems in the testing infrastructure 600. However, in some embodiments the test management system 602 and simulation system 604 are a single system that manages and executes scenarios used to test, validate, and verify performance of a system under test, such as the AV compute 606. The AV compute 606 is communicatively coupled with the test management system 602 and the simulation system 604. In examples, the AV compute 606 is offline (e.g., does not execute on a deployed vehicle), and is similar to or the same as autonomous vehicle compute 202f as described with respect to FIG. 2 or the autonomous vehicle compute 400 described with respect to FIG. 4. In examples, during simulation the AV compute 606 outputs data that is obtained by the simulation system 604.

The AV compute 606 is tested, validated, or verified by interpreting the response or behavior of the AV compute 606 to scenarios 642. In examples, results of the simulations of scenarios 642 are used in root cause analysis to update or further develop the autonomous system (e.g., AV compute 606). The autonomous system is then deployed in the real world (e.g., AV compute 606 is deployed on a vehicle that operates in the real world) after meeting various standards verified via the simulation of scenarios 642. In examples, the scenarios 642 are based on data 622 as obtained by the test management system 602. The scenarios 642 are representative of a simulated environment in which a simulated autonomous vehicle operates as controlled by the AV compute 606. The scenarios 642 includes simulated data, such as simulated time series data. The simulated data is, for example, simulated inputs of one or more devices such as cameras 202a, LiDAR sensors 202b, radar sensors 202c, microphones 202d, and communication device 202e. In examples, the scenarios 642 include data provided as input to perception system 402, planning system 404, localization system 406, control system 408, and database 410 as described with respect to FIG. 4.

The simulation system 604 includes vehicle dynamics 644. In examples, vehicle dynamics 644 simulates outputs representative of vehicle dynamics. For example, vehicle dynamics include simulated outputs of one or more devices such as drive-by-wire (DBW) system 202h, safety controller 202g, powertrain control system 204, steering control system 206, and brake system 208. For ease of description, the scenarios 642 and vehicle dynamics 644 are described as simulated data associated with the operation of vehicle systems and provided to AV compute 606. However, in some embodiments the vehicle systems such as cameras 202a, LiDAR sensors 202b, radar sensors 202c, microphones 202d, communication device 202e, drive-by-wire (DBW) system 202h, safety controller 202g, powertrain control system 204, steering control system 206, and brake system 208 are tested, validated, or verified by obtaining simulated data from the simulation system 604.

The test management system 602 enables coordination of testing, validation, and verification of the AV compute 606. For example, the test management system 602 can obtain one or more conditions that are evaluated during a simulation. In examples, the conditions are specified by a user and input to the test management system. The condition is, for example, a test objective, feature, function, and/or behavior of an autonomous system. A condition is a functionality that the autonomous vehicle is expected to perform or a function under development. A condition can be, for example, a vehicle picking up a passenger, picking up or dropping off a trailer, and the like. In examples, a condition is the occurrence of event sequences. For ease of description, the present techniques are described using the detection of an object track as a condition (e.g., object tracking). However, any condition of the AV can be tested according to the present techniques.

The test management system 602 includes test data 622. The test data 622 is used to construct scenarios 642. In examples, the test data 622 is real world data, such as drive logs. Drive logs include data captured by various subsystems, sensors, and devices as a vehicle navigates in an environment. In examples, the test data 622 includes varying, inconsistent characteristics associated with agents detected by vehicles deployed in the real world. A sequencer 626 enables consistent characteristics of agents. The test data 622 and the sequencer 626 are used to create scenarios 642. The scenarios 642 are input into an AV compute 606 to evaluate the performance of the AV compute.

The test management system 602 includes an observer 624. The observer 642 automatically verifies a set of conditions. In examples, the observer 642 verifies that the performance of the AV compute 606 during simulation satisfies criteria associated with at least one condition based on the observed characteristics. In some embodiments, the observer 642 identifies an object/agent, and tests the characteristics as observed (e.g., perceived) by the AV system. Moreover, the observer 642 tests a combination of characteristics, and/or characteristics derived from the observed characteristics. In examples, the observer tests whether an object/agent will follow a certain prescribed behavior sequence.

In the example of object tracking as a condition, the observer 624 verifies that a track output by the AV compute as corresponding to an agent is accurate. For examples, the observer 624 ensures that a same object is observed (e.g., in object tracking, the observed object is tracked) an event sequence tunnel. In some simulations, the verification is done by human observers that determine whether a condition passes or fails during a single time/frame (e.g. whether an object/track is detected within a specified region during a particular time/frame or duration) during a visual inspection of each frame. In these simulations, the pass and fail determinations are aggregated across multiple time/frames to arrive at an overall pass/fail assessment. Additionally, in these simulations, existing ground truth track specifications can be used to check object/track existence over multiple frames within some distance specification of the ground truth track. Determining whether a condition passes or fails during a single frame (e.g., at a single point in time) limits the detection of conditions based on observed characteristics that occur over multiple frames. When evaluating a single time/frame, the consistency of characteristics across multiple frames cannot be tested (e.g. track of a single object, which should have same track identification in each frame). Additionally, for events lasting over many frames, specifications of such characteristics for testing is tenuous based on evaluations for a single time/frame. In some embodiments, the observer 624 performs automatic evaluation of one or more conditions in response to a scenario. For example, the observer 624 determines if a single track traverses an event sequence tunnel over a specified time range (e.g., at a first timestamp and subsequent timestamps, through each spaces and waypoints, and the tunnel in between). Event sequence tunnels, spaces, and waypoints are further described below.

In examples, a sequencer 626 outputs objects/agents with characteristics corresponding to events that occur in the test data 622. Events can be selected manually in a point and click fashion on an interactive map corresponding to the scenario, or waypoints can be automatically be placed based on a final destination point a routing from point of origin. In examples, an event refers to something that happens or occurs during a simulation. An event is associated with a point or area of the scenario. An event is a detection such as a detected object, a detected occurrence, or other detections in the scenario. For example, an event is a light turning on in an area (e.g., a blinker being activated, brake lights, traffic lights changing colors), an object detection at a location or within an area, and the like. In some embodiments, the event evolves over time. For example, the event is associated with some state that changes over time, such as moving through the environment.

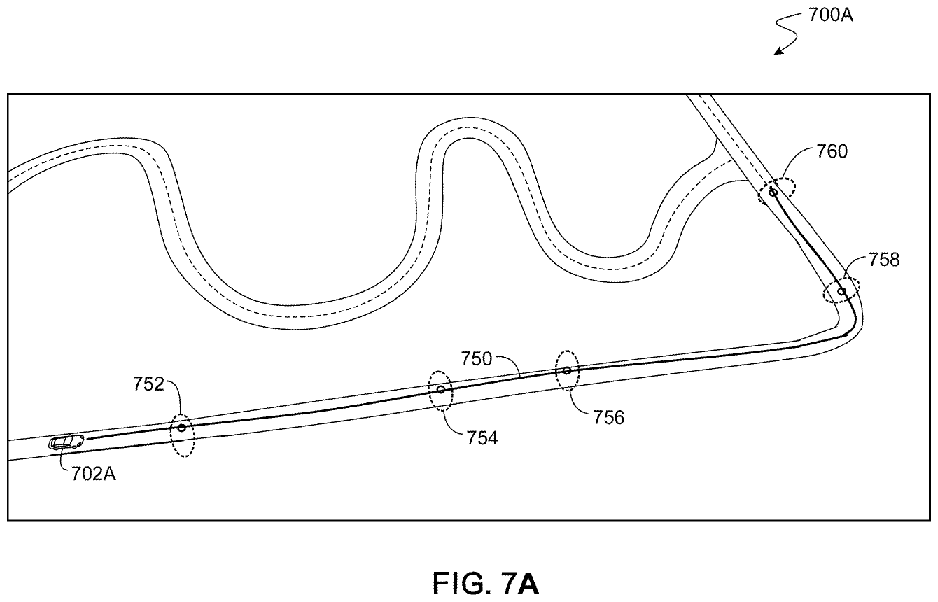

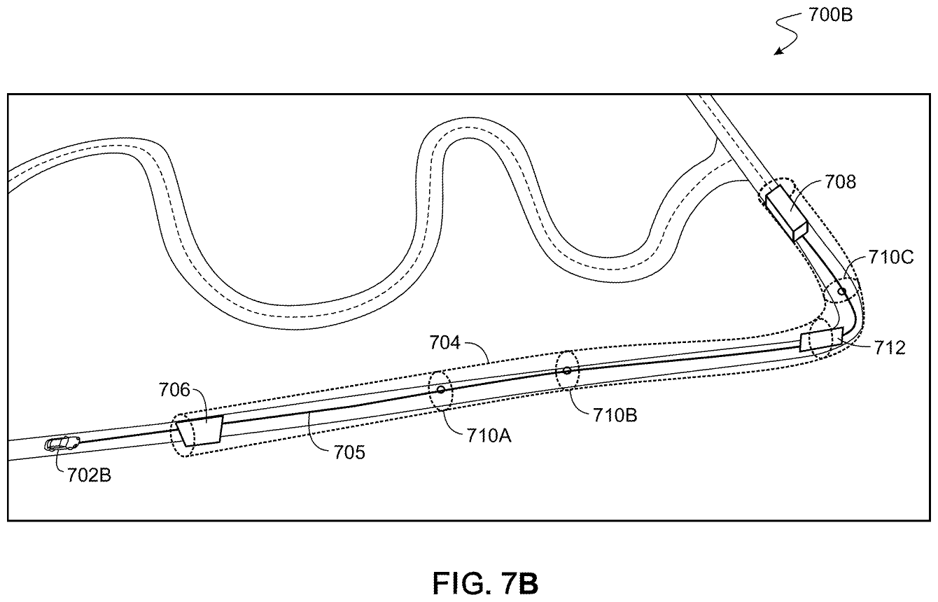

In some embodiments, an event sequence tunnel is a portion of the simulated environment associated with an event, designated by an entry space and an exit space as described with respect to FIG. 7B. For ease of explanation, the event is described as a detected agent, and characteristics of the agent are retrieved and used for evaluating the conditions starting from the entry space, through the event sequence tunnel, all the way to the exit space. However, the present techniques are not limited to event sequences corresponding to agents. As shown in FIG. 7A, the event sequence is defined by time interval with a first timestamp and subsequent timestamps that follow the first timestamp. A characteristic is captured at the first timestamp and replicated through the subsequent timestamp to a final timestamp.

The test data 622 and sequencer 626 provide data for use in a scenarios 642 for simulation. The sequencer 626 defines event sequences that are evaluated during simulation of a scenarios 642 at the AV compute 606. For example, each simulated agent in a scenario is associated with an event sequence tunnel. Within the event sequence tunnel, consistent characteristics are applied to each frame of the scenario on/against the agent. For example, an agent detected at an entry space of an event sequence tunnel in a first frame of the scenario is assigned a first identification, wherein the first identification is a characteristic associated with the agent. At the event sequence tunnel in subsequent frames, the same agent is assigned the same first identification. The event sequence tunnel is specified such that consistent characteristics are propagated for an agent across frames of a scenario, resulting in a scenario that includes consistent characteristics of agents within a respective event sequence tunnel. In examples, consistency of characteristics refers to characteristics that are equal, congruent, within some range from the adjacent time/frame, or follow a predetermined pattern of evolution through part or whole of an event sequence tunnel. A response of the AV compute 606 in a simulation of a scenario is validated in view of consistent characteristics of the simulated agents in the scenario. In this manner, consistency of characteristics is enforced in the scenarios.

In some embodiments, when repeatedly simulating a scenario one or more characteristics of an object (e.g., an event) may evolve. In examples, the characteristics are assigned during the runtime of programs that execute the simulation. The objects/agents output by the sequencer to describe the environment are associated with a first set of characteristics (e.g., ground truth characteristics). In examples, the first set of characteristics are assigned at runtime of the simulation application. Additionally, the AV system, may prescribe a second set of characteristics to these objects/agents (e.g., observed characteristics) when responding to the scenario during a simulation. Some of characteristics in the first set of characteristics and the second set of characteristics may overlap. For example, at a component/task level re-simulation characteristics in the first set of characteristics and the second set of characteristics frequently overlap, such that the characteristics are equal, congruent, within some range from the adjacent time/frame, or follow a predetermined pattern of evolution. In a component/task level re-simulation, results from one task/component is fed into the next. For example, during a tracking re-simulation, an autonomous system obtains as input detection results from a tracking task with a LiDAR point cloud (e.g., the first set of characteristics) as input. The tracking task outputs characteristics (e.g., the second set of characteristics) of detected objects (position, velocity, dimension, color, etc.) As these outputs are not ground truth, in examples the tracking task iteratively processes or re-interprets the detected objects and makes corrections to its output, updating the second set of characteristics. For example, the characteristics assigned by the AV can change due to modifications in algorithms, weights, or some other features of the programs of the AV. In examples, the first set of characteristics and the corrected/updated characteristics in the second set of characteristics may be of the same type. The present techniques enable consistent characteristics within a predetermined time interval or event sequence tunnel as described below, as determined at runtime of the test management system 602, simulation system 604, and/or the system under test (e.g., the autonomous system 606).

The present techniques enable a testing observer that automatically verifies one or more conditions by retrieving at least one characteristic from a first occurrence of an event in a current simulation or from a previous simulation. A first occurrence of an event can define a first timestamp in a scenario input to the system under test, and characteristics are observed by the system under test at the first timestamp. In examples, an entry space defines an area or point in time at which the characteristics of an event are captured. The at least one characteristic is used to represent the event or simulated agent across a time interval. Through the time interval, the at least one characteristic is automatically assigned to the event or simulated agent according to at least one expected parameter. For example, the at least one characteristic is represented in the scenario as being equal to the same characteristic at the entry space, within some range from the adjacent time/frame, or as following a predetermined pattern of evolution through part or whole of an event sequence tunnel. In some embodiments, the characteristic evolves through frames of the scenario associated with the event sequence tunnel according and remains the same (e.g., is equal), congruent, within some range from the adjacent time/frame, or follows a predetermined pattern of evolution. As the characteristic evolves, the characteristic is replicated by assigning characteristic to the simulated agent for frames of the scenario, and scenarios are iteratively executed. The present techniques overcome observations that are limited to (1) determining that an event occurred or did not occur in a particular area at a particular time and (2) determining that the event that occurred or did not occur has a fixed characteristic (e.g. is a vehicle instead of a bicycle).

FIGS. 7A and 7B shows scenarios 700A and 700B, respectively. In examples, the scenario 700A and scenario 700B are executed via simulations of the vehicles 102 of FIG. 1, vehicle 200 of FIG. 2, device 300 of FIG. 3, AV compute 400 of FIG. 4, vehicle 502 of FIG. 5, or using the testing infrastructure 600 of FIG. 6. For ease of illustration, a single agent 702A, corresponding time interval (including timestamps 754, 756, 758, and 760), a single agent 702B, and corresponding event sequence tunnel 704 are illustrated in FIGS. 7A and 7B. However a scenario can include any number of agents, time intervals, and corresponding event sequence tunnels.

In the scenario 700A of FIG. 7A, a time interval is specified for the simulated agent 702A along trajectory 750 by at least a first timestamp 752. Subsequent timestamps 754, 756, 758, and 760 are defined by a location on the trajectory 750. In examples, the scenario 700A is simulated at an AV compute (e.g., AV compute 606 of FIG. 6). A test management system (e.g., test management system 602 of FIG. 6) identifies events in the scenario 700A. A first timestamp 752 and a last timestamp 760 are specified for an identified event. At least one characteristic is observed at the first timestamp 752, and the last timestamp 760 is selected the end of a time interval starting at the first timestamp 752 or other location to end observation of the simulated agent. The characteristics observed at the first timestamp are propagated through the subsequent frames by determining associations between characteristics across frames of the scenario according to at least one parameter. In the example of object tracking with an identification of the simulated object as a characteristic, the at least one parameter is dimensions of the simulated object, and associations are dimensions that change across timestamps as views of the object change are determined. Characteristics include, for example, an object/agent's perceived dimensions. In an example, the object/agent's observed characteristic is tested to determine if the whether the observed characteristic fits a predetermined pattern of evolvement (e.g. heading needs to evolve to fit a curved trajectory).

The associations evolve across iterative executions of the scenario. This results in characteristics for the agent 702A that are consistent for a predefined time interval according to the observed characteristic that evolves according to an expected parameter and resulting associations across frames of the simulation. In examples, the characteristics are, for example, include an identification, velocity, and dimensions of the simulated agent. Additionally, the characteristics include, for example, a tracking/object identification, the agent's length/width/height/wheelbase length, and the agent's motion characteristics such as velocity, acceleration, heading, yawing rate, and the like as detected at the entry space. The captured characteristics corresponding to the simulated agent 702A are consistent throughout timestamps 752, 754, 756, 758, and 760 of the simulation of the scenario 700A. In a subsequent execution of the same scenario 700A, the characteristics of the agent 702A can be different from a previous execution, even with a same timestamps 752, 754, 756, 758, and 760 identified. However, in each execution of the same scenario 700A, the characteristics as observed at the first timestamp 752 are consistent within the time interval across all frames of the scenario.

FIG. 7B shows a scenario 700B, where the object tracking response of an autonomous system is evaluated. In the example of FIG. 7B, the at least one characteristic observed by the autonomous system is an identification of the simulated agent, and the at least one parameter corresponds to dimensions associated with the simulated agent as observed in frames of the scenario during simulation. FIG. 7B includes an event sequence tunnel, which is a two-dimensional (2D) or three-dimensional (3D) portion of the simulated environment including a corresponding agent at some point in time.

In the scenario 700B, an event sequence tunnel 704 is specified for the simulated agent 702 by an entry space 706 and an exit space 708. The entry space 706 and the exit space 708 are defined by a location on a trajectory 705 of an agent at a timestamp (e.g., predetermined points in time), or by a time interval. In examples, the entry space 706 and the exit space 708 are 2D or 3D spaces associated with coordinates that represent locations in the simulated environment. Within the event sequence tunnel 704, waypoints 710A, 710B, and 710C are identified. Additionally, intermediate space 712 is identified.

In examples, the scenario 700B is simulated at an AV compute (e.g., AV compute 606 of FIG. 6). A test management system (e.g., test management system 602 of FIG. 6) identifies events in the scenario 700B. An entry space and exit space are specified for an identified event. In the example of a detected object, an entry space can be selected as the space where the detection occurs and the exit space specified by a time interval or other location to end tracking of the object. The characteristics observed at the entry space are propagated through the event sequence tunnel by narrowly sizing the tunnel according to at least one parameter to capture the detected object in each frame of the scenario. This results in consistent characteristics for the agent 702B within the event sequence tunnel, as identified by the entry space 706 and exit space 708. For example, the entry space 706 and exit space 708 are identified, and the characteristics corresponding to the agent 702 are captured at the entry space 706. The captured characteristics corresponding to the simulated agent 702 are consistent throughout frames of the scenario where the agent 702 is located within the event sequence tunnel. The agent (e.g., agent with consistent characteristics) persists in frames of the scenario until the exit space 708 is reached. At the exit space 708, the agent characteristics are consistent with the characteristics simulated at the entry space 706. In a subsequent execution of the same scenario 700B, the characteristics of the agent 702 can be different from a previous execution, even with a same entry space 706 and a same exit space 708. However, in each execution of the same scenario 700B, the characteristics as simulated at the entry space 706 are consistent within the event sequence tunnel 704 across all frames of the scenario.

In some examples, waypoints 710A, 710B, and 710C (collectively referred to as waypoints 710) and intermediate space 712 are identified in the event sequence tunnel. One or more waypoints or intermediate spaces are injected into the event sequence tunnel to further specify locations included in an event sequence tunnel associated with a respective agent. Similar to entry/exit spaces, an intermediate space is defined by a location on a trajectory 705 of an agent at a timestamp or by a time interval. In examples, the intermediate space is a 2D or 3D space associated with coordinates that represent locations in the simulated environment. A waypoint refers to a point or location associated with a timestamp or time interval. In examples, waypoints are injected into the event sequence tunnel between specifications of spaces (e.g., entry space, exit space, intermediate space) in order to use the spaces on each side of a respective waypoint to make implications, such as object permanence. Waypoints are used to indicate locations within the event sequence tunnel where an event occurs, such as a particular location at an intersection of interest. An intermediate space is used to indicate 3D volumes within the event sequence tunnel where a test event occurs, such as an intersection including multiple lanes of traffic and traffic control signals. In examples, the waypoints 710 and intermediate space 712 are specified with or without a timestamp or time interval. Additionally, in examples, the waypoints 710 and intermediate space 712 are injected based on one or more conditions that are evaluated during a simulation. For example, in a positive test condition verified via simulation, waypoints are injected to verify that the agent appears within the event sequence tunnel at particular locations. In a negative test condition verified during simulation, an intermediate space is injected to verify that the agent does not appear within the intermediate space.

In some embodiments, curve fitting algorithms are used to derive a trajectory and the dimension of the event sequence tunnel from the entry spaces, exit spaces, waypoints, and intermediate spaces. In some embodiments, curve fitting algorithms are used to define one or more parameters associated with a simulated agent. For example, a trajectory is identified by constructing a curve or mathematical function that has a best fit to a series of data points associated with the agent. Curve fitting algorithms include, for example, least squares, smoothing, regression analysis, time series analysis, and the like. In examples, the event sequence tunnel is defined based on the trajectory of the agent. A factor or a sequence of factors is also used to define some amplification or shrinkage of the interior dimensions of the event sequence tunnel relative to the size of the entry space, exit space, intermediate spaces, and waypoints. For example, algorithms are applied to the interior dimension of the event sequence tunnel to evolve interior dimensions from known adjacent spaces by a multiplicative factor. The event sequence tunnel is sized to encompass the corresponding agent from the entry space to the exit space.

In some embodiments, a sequence of shrinkage or amplification factors includes parameters applied to the event sequence tunnel between two adjacent spaces and/or waypoints. By applying the sequence of factors to the event sequence tunnel, the event sequence tunnel is narrowly specified to capture the corresponding agent while avoiding other agents or events. The consistent characteristics are then applied to the agent within the event sequence tunnel for each frame of the scenario. In the example of FIG. 7B, an algorithm is applied to the dimensions of the entry space 706 to determine dimensions of the event sequence tunnel between the entry space 706 and the intermediate space 712. Shrinkage or expansion factors are applied to one or more points or areas within the event sequence tunnel 704 to ensure the size of the event sequence tunnel is large enough to include the volume of points corresponding to the agent as it moves through the event sequence tunnel 704 during a simulation, and to exclude other agents and events from the event sequence tunnel. In an example, a larger event tunnel is specified when a scenario is sparse with few agents or events to ensure the entire agent is captured. As the number of agents or events in a scenario increases, a shrinkage factor is applied to the event sequence tunnel to narrowly capture the corresponding agent in the scenario, while avoiding other agents and events. In examples, an event sequence tunnel is specified for hundreds of frames and captures the corresponding agent across the entire event sequence tunnel without manually specifying each frame.

In examples, the event sequence tunnel is generated by determining that an event took place in the entry space (e.g., an agent was detected), the event continued in every frame through the event sequence tunnel until the exit space. In the event sequence tunnel, characteristics of the event the occur successively through the event sequence tunnel and are consistent with adjacent occurrences in time, starting from the occurrence in the entry space and ending with the occurrence in the exit space. The present techniques enable scenarios where an event (e.g., detected agent) is known to be present and consistently identified across a sequence of frames during a simulation. In examples, a simulation is performed that evaluates the AV's ability to accurately track an agent across a large number of frames (e.g., a simulation more than a few seconds in length). In some embodiments, consistency of other characteristics of the detected event are evaluated for consistency, such as the color associated with a detected object, a speed of a detected object, and the like. The simulation is executed without a human observer and automatically returns a pass/fail condition of the simulation.

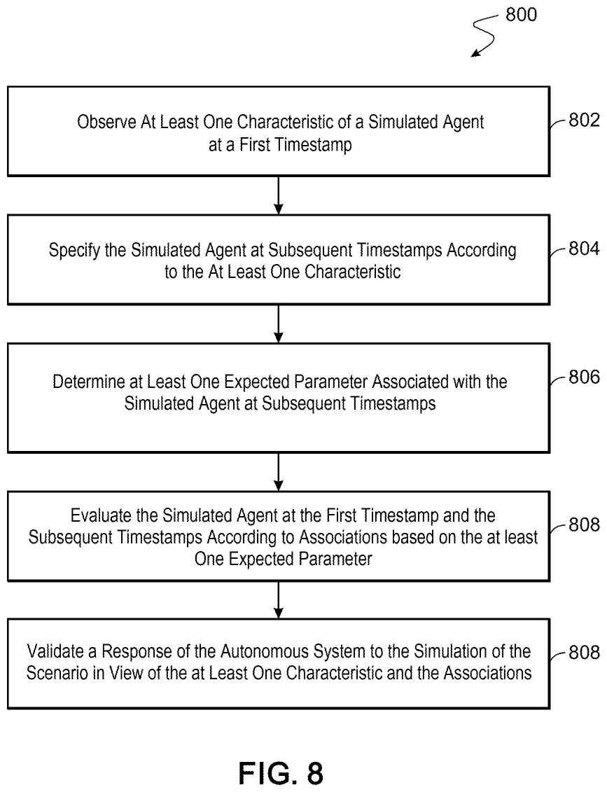

Referring now to FIG. 8, illustrated is a flowchart of a process 800 for defining and testing evolving event sequences. In some embodiments, one or more of the steps described with respect to process 800 are performed (e.g., completely, partially, and/or the like) autonomous vehicle (AV) system 114, fleet management system 116 described in FIG. 1, vehicle 200 of FIG. 2, device 300 of FIG. 3, autonomous vehicle compute 400 of FIG. 4, AV compute 504 of FIG. 5, of testing infrastructure 600.

At block 802, at least one characteristic of a simulated agent is observed at a first timestamp during a simulation of a scenario. In some embodiments, the first timestamp is determined according to an event of the scenario. For example, when the simulated agent reaches a predetermined location, a first timestamp occurs. In examples, the at least one characteristic is a location of the simulated agent and the at least one expected parameter is a next location of the simulated agent. In examples, the at least one characteristic is an object color of the simulated agent and the at least one expected parameter is a subsequent color of the simulated agent.

At block 804, the simulated agent is specified at subsequent timestamps according to the at least one characteristic in the scenario, where the at least one characteristic is observed at the first timestamp. In some embodiments, a predefined time interval is used to determine subsequent timestamps in the scenario. Additionally, in some embodiments one or more events are used to determine subsequent timestamps in the scenario.

At block 806, at least one expected parameter associated with the simulated agent at the subsequent timestamps is determined. In some embodiments, the at least one expected parameter is modified responsive to other simulation features. In examples, the at least one characteristic is an object identification and an event sequence tunnel is specified by at entry space at the first timestamp and an exit space at a subsequent timestamp. In such an example, the at least one expected parameter is one or more dimensions of the event sequence tunnel, wherein at least one factor is applied to dimensions of the event sequence tunnel at the entry space and propagated through the event sequence tunnel. In some embodiments, the other simulation features are used to inform the at least one expected parameter. In an example where the at least one expected parameter is one or more dimensions of the event sequence tunnel, the dimensions are selected such that interference with other simulation features is minimized. Other simulation features include, for example, other simulated agents. Other simulation features can also include environmental conditions or other constraints imposed on the simulated agent. In an example where the at least one characteristic is a location, the at least one expected parameter can be a heading or direction of travel. Other simulation features, such as acceleration, velocity, or weather conditions are used to update or modify the heading or direction of travel of the simulated agent.

At block 808, the simulated agent is evaluated at the first timestamp and the subsequent timestamps, wherein associations among characteristics associated with the simulated agent are determined starting at the first timestamp through the subsequent timestamps, and wherein the associations evolve across iterative simulations of the scenario. In embodiments, the characteristics evolve across iterative simulations of the scenario. The same simulated agent is identified across the iterative simulations of the scenario, wherein consistent characteristics of the same simulated agent are determined at the first timestamp in respective scenarios executed by the iterative simulations.

At block 810, a response of an autonomous system in the iterative simulations of the scenario is validated, wherein the simulated agent is consistently simulated according to the at least one characteristic and associations at the first timestamp and subsequent timestamps.

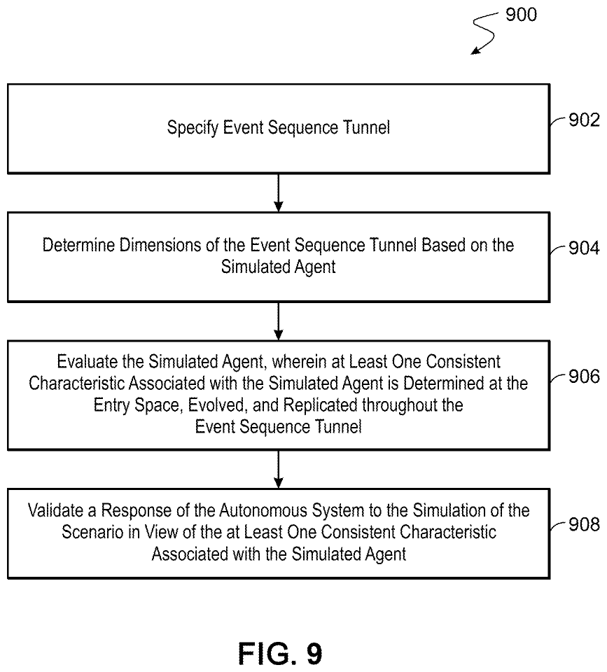

Referring now to FIG. 9, illustrated is a flowchart of a process 900 for defining and testing evolving event sequences. In some embodiments, one or more of the steps described with respect to process 900 are performed (e.g., completely, partially, and/or the like) autonomous vehicle (AV) system 114, fleet management system 116 described in FIG. 1, vehicle 200 of FIG. 2, device 300 of FIG. 3, autonomous vehicle compute 400 of FIG. 4, AV compute 504 of FIG. 5, of testing infrastructure 600.

At block 902, an event sequence tunnel is specified, wherein an entry space and an exit space of the event sequence tunnel are identified for a simulated agent. In examples, the event sequence tunnel is identified according to a respective trajectory of the simulated agent. In examples, the event sequence tunnel is specified by a time interval or by points in time that designate the entry space and the exit space. The event sequence tunnel corresponds to locations in the simulated environment. At block 904, dimensions of the event sequence tunnel are determined based on the simulated agent, wherein at least one factor is applied to dimensions of the event sequence tunnel at the entry space and propagated through the event sequence tunnel. In examples, the dimensions of the event sequence tunnel are determined according to a shrinkage or expansion factor, and multiple such factors (e.g., a combination of multiple shrinkage or expansion factors assigned to one or more frames of a scenario) may be specified for a section of the tunnel. The characteristics observed at the entry space are propagated through the event sequence tunnel by narrowly sizing the tunnel according to the dimensions of the simulated agent. For example, the expansion/shrinkage factors increase/decrease the size of the event sequence tunnel so that the simulated agent (e.g., a detected object) is entirely encompassed within the 2D or 3D space corresponding to a respective event sequence tunnel in each frame of the scenario.

At block 906, the simulated agent is evaluated at the entry space, until the exit space of the event sequence tunnel in a simulation of the scenario, wherein at least one consistent characteristic associated with the simulated agent is determined at the entry space and replicated throughout event sequence tunnels. The characteristics can evolve across iterative simulations of the scenario. The same simulated agent is identified across the iterative simulations of the scenario, wherein consistent characteristics of the same simulated agent are determined at the entry space of event sequence tunnels in respective scenarios executed by the iterative simulations. In some embodiments, waypoints or intermediate spaces are injected in the event sequence tunnel corresponding to the simulated agent. In examples, the entry space, the exit space, the waypoints, and the intermediate spaces are defined by a point in time or a time interval.

In examples, the at least one consistent characteristic is a value for the characteristic associated with the simulated agent at the entry space, until the exit space, and through the waypoints and the intermediate spaces of the event sequence tunnel in a respective scenario. As a result, within the event sequence tunnel, the simulated agent is associated with the same characteristic as the same simulated agent at the entry space in the respective scenario.

At block 908, a response of an autonomous system is validated during simulations of a scenario in view of the at least one consistent characteristic of the simulated agent. In examples, the autonomous system passes or is verified when the response of the autonomous system accurately responds to the at least one consistent characteristic. The response of the autonomous system is validated at the entry space, exit space, and any waypoints or intermediate spaces of the event sequence tunnel. In examples, validating the response of the autonomous system to the simulation of the scenario includes executing a tracking algorithm of the autonomous system on time series data of the scenario and determining that the tracking algorithm identified a threshold amount of consistent characteristics across frames of the scenario. In this manner, the AV tracking functionality in view of consistently characterized agents within respective event sequence tunnels is evaluated. Thus, the present techniques enable testing of event sequences using characteristics of extracted detections that occur in the scenario instead of pre-specified characteristics. Additionally, the present techniques streamline specification of event sequence tunnels over multitude of frames to a few waypoints and entry, exit and intermediate spaces by a user graphically inserting the waypoints, entry, exit and intermediate spaces on a visual representation of the scenario. Such specifications and tests of event sequences accounts for overwhelming majority of AV tracking and the design/test/monitor of robotic action sequences. The present techniques streamline the specification process.

According to some non-limiting embodiments or examples, provided is a system including at least one processor and at least one non-transitory storage media. The at least one non-transitory storage media stores instructions that, when executed by the at least one processor, cause the at least one processor to perform operations. The operations include observing at least one characteristic of a simulated agent at a first timestamp during a simulation of a scenario. The operations include specifying the simulated agent at subsequent timestamps according to the at least one characteristic in the scenario. The operations include determining at least one expected parameter associated with the simulated agent at the subsequent timestamps, wherein the at least one expected parameter is modified responsive to other simulation features. The operations include evaluating the simulated agent at the first timestamp and the subsequent timestamps, wherein associations among characteristics associated with the simulated agent are determined starting at the first timestamp through the subsequent timestamps, and wherein the associations evolve across iterative simulations of the scenario. Additionally, the operations include validating a response of an autonomous system in the iterative simulations of the scenario wherein the simulated agent consistently simulated according to the at least one characteristic at the first timestamp and subsequent timestamps.

According to some non-limiting embodiments or examples, provided is a method. The method includes capturing, with at least one processor, at least one characteristic of a simulated agent at a first timestamp during a simulation of a scenario. The method includes specifying, with at the least one processor, the simulated agent at subsequent timestamps according to the at least one characteristic in the scenario. The method includes determining, with at the least one processor, at least one expected parameter associated with the simulated agent at the subsequent timestamps, wherein the at least one expected parameter is modified responsive to other simulation features. The method includes evaluating, with at the least one processor, the simulated agent at the first timestamp and the subsequent timestamps, wherein associations among characteristics associated with the simulated agent are determined starting at the first timestamp through the subsequent timestamps, and wherein the associations evolve across iterative simulations of the scenario. Additionally, the method includes validating, with at the least one processor, a response of an autonomous system in the iterative simulations of the scenario wherein the simulated agent consistently simulated according to the at least one characteristic at the first timestamp and subsequent timestamps.

According to some non-limiting embodiments or examples, provided is at least one non-transitory storage media storing instructions that, when executed by at least one processor, cause the at least one processor to perform operations. The operations include observing at least one characteristic of a simulated agent at a first timestamp during a simulation of a scenario. The operations include specifying the simulated agent at subsequent timestamps according to the at least one characteristic in the scenario. The operations include determining at least one expected parameter associated with the simulated agent at the subsequent timestamps, wherein the at least one expected parameter is modified responsive to other simulation features. The operations include evaluating the simulated agent at the first timestamp and the subsequent timestamps, wherein associations among characteristics associated with the simulated agent are determined starting at the first timestamp through the subsequent timestamps, and wherein the associations evolve across iterative simulations of the scenario. Additionally, the operations include validating a response of an autonomous system in the iterative simulations of the scenario wherein the simulated agent consistently simulated according to the at least one characteristic at the first timestamp and subsequent timestamps.

According to some non-limiting embodiments or examples, provided is a system including at least one processor and at least one non-transitory storage media. The at least one non-transitory storage media stores instructions that, when executed by the at least one processor, cause the at least one processor to perform operations. The operations include specifying an event sequence tunnel in a scenario, wherein an entry space and an exit space of the event sequence tunnel are identified for a simulated agent. The operations include determining dimensions of the event sequence tunnel based on the simulated agent, wherein at least one factor is applied to dimensions of the event sequence tunnel at the entry space and propagated through the event sequence tunnel. Additionally, the operations include evaluating the simulated agent at the entry space, until the exit space of the event sequence tunnel in a simulation of the scenario, wherein at least one consistent characteristic associated with the simulated agent is determined at the entry space, evolves across iterative simulations of the scenario, and is replicated throughout event sequence tunnels of respective scenarios. The operations also include validating a response of an autonomous system to simulations of the scenario.

According to some non-limiting embodiments or examples, provided is a method. The method includes specifying, with at least one processor, an event sequence tunnel in a scenario, wherein an entry space and an exit space of the event sequence tunnel are identified for a simulated agent. The method also includes determining, with the at least one processor, dimensions of the event sequence tunnel based on the simulated agent, wherein at least one factor is applied to dimensions of the event sequence tunnel at the entry space and propagated through the event sequence tunnel. The method includes evaluating, with the at least one processor, the simulated agent at the entry space, until the exit space of the event sequence tunnel in a simulation of the scenario, wherein at least one consistent characteristic associated with the simulated agent is determined at the entry space, evolves across iterative simulations of the scenario, and is replicated throughout event sequence tunnels of respective scenarios. Additionally, the method includes validating, with the at least one processor, a response of an autonomous system to simulations of the scenario in view of the at least one consistent characteristic of the simulated agent.

According to some non-limiting embodiments or examples, provided is at least one non-transitory storage media storing instructions that, when executed by at least one processor, cause the at least one processor to perform operations. The operations include specifying an event sequence tunnel in a scenario, wherein an entry space and an exit space of the event sequence tunnel are identified for a simulated agent. The operations include determining dimensions of the event sequence tunnel based on the simulated agent, wherein at least one factor is applied to dimensions of the event sequence tunnel at the entry space and propagated through the event sequence tunnel. Additionally, the operations include evaluating the simulated agent at the entry space, until the exit space of the event sequence tunnel in a simulation of the scenario, wherein at least one consistent characteristic associated with the simulated agent is determined at the entry space, evolves across iterative simulations of the scenario, and is replicated throughout event sequence tunnels of respective scenarios. The operations also include validating a response of an autonomous system to simulations of the scenario in view of the at least one consistent characteristic of the simulated agent.

Further non-limiting aspects or embodiments are set forth in the following numbered clauses:
Clause 1: A system, comprising: at least one processor, and at least one non-transitory storage media storing instructions that, when executed by the at least one processor, cause the at least one processor to: observe at least one characteristic of a simulated agent at a first timestamp during a simulation of a scenario; specify the simulated agent at subsequent timestamps according to the at least one characteristic in the scenario; determine at least one expected parameter associated with the simulated agent at the subsequent timestamps, wherein the at least one expected parameter is modified responsive to other simulation features; evaluate the simulated agent at the first timestamp and the subsequent timestamps, wherein associations among characteristics associated with the simulated agent are determined starting at the first timestamp through the subsequent timestamps, and wherein the associations evolve across iterative simulations of the scenario; and validate a response of an autonomous system in the iterative simulations of the scenario wherein the simulated agent consistently simulated according to the at least one characteristic at the first timestamp and subsequent timestamps.
Clause 2: The system of clause 1, wherein the at least one characteristic is a location of the simulated agent and the at least one expected parameter is a next location of the simulated agent.
Clause 3: The system of clauses 1 or 2, wherein the at least one characteristic is an object color of the simulated agent and the at least one expected parameter is a subsequent color of the simulated agent.
Clause 4: The system of any of clauses 1-3, wherein the at least one characteristic is an object identification and an event sequence tunnel is specified by at entry space at the first timestamp and an exit space at a subsequent timestamp.
Clause 5: The system of clause 4, wherein the at least one expected parameter is one or more dimensions of the event sequence tunnel, wherein at least one factor is applied to dimensions of the event sequence tunnel at the entry space and propagated through the event sequence tunnel.
Clause 6: The system of clause 4, wherein evaluating the simulated agent at the first timestamp and the subsequent timestamps comprises associating a consistent identification of the simulated agent in the iterative simulations of the scenario.
Clause 7: The system of clause 4, wherein at least one waypoint or at least one intermediate space is injected into in the event sequence tunnel identified for the simulated agent, and the simulated agent is evaluated at the entry space, then at least at one waypoint or at one intermediate space, and the exit space.
Clause 8: The system of any of clauses 1-7, wherein the at least one characteristic is a value associated with an agent captured at an entry space corresponding to the first timestamp, until an exit space corresponding to a last timestamp, through at least one waypoint or at least one intermediate space of the event sequence tunnel.
Clause 9: The system of any of clauses 1-8, wherein the at least one characteristic is an agent identification, an agent type, an agent velocity, an agent dimension, an agent shape, an agent color, or any combinations thereof.
Clause 10: The system of any of clauses 1-9, wherein validating the response of the autonomous system to the simulation of the scenario comprises executing a tracking algorithm of the autonomous system on time series data of the scenario and determining that the tracking algorithm identified a threshold amount of consistent characteristics across frames of the scenario.
Clause 11: A method comprising: capturing, with at least one processor, at least one characteristic of a simulated agent at a first timestamp during a simulation of a scenario; specifying, with at the least one processor, the simulated agent at subsequent timestamps according to the at least one characteristic in the scenario; determining, with at the least one processor, at least one expected parameter associated with the simulated agent at the subsequent timestamps, wherein the at least one expected parameter is modified responsive to other simulation features; evaluating, with at the least one processor, the simulated agent at the first timestamp and the subsequent timestamps, wherein associations among characteristics associated with the simulated agent are determined starting at the first timestamp through the subsequent timestamps, and wherein the associations evolve across iterative simulations of the scenario; and validating, with at the least one processor, a response of an autonomous system in the iterative simulations of the scenario wherein the simulated agent consistently simulated according to the at least one characteristic at the first timestamp and subsequent timestamps.
Clause 12: The method of clause 11, wherein the at least one characteristic is a location of the simulated agent and the at least one expected parameter is a next location of the simulated agent.
Clause 13: The method of any of clauses 11 or 12, wherein the at least one characteristic is an object color of the simulated agent and the at least one expected parameter is a subsequent color of the simulated agent.
Clause 14: The method of any of clauses 11-13, wherein the at least one characteristic is an object identification and an event sequence tunnel is specified by at entry space at the first timestamp and an exit space at a subsequent timestamp.
Clause 15: The method of clause 14, wherein the at least one expected parameter is one or more dimensions of the event sequence tunnel, wherein at least one factor is applied to dimensions of the event sequence tunnel at the entry space and propagated through the event sequence tunnel.
Clause 16: The method of clause 14, wherein evaluating the simulated agent at the first timestamp and the subsequent timestamps comprises associating a consistent identification of the simulated agent in the iterative simulations of the scenario.
Clause 17: The method of clause 14, wherein at least one waypoint or at least one intermediate space is injected into in the event sequence tunnel identified for the simulated agent, and the simulated agent is evaluated at the entry space, then at least at one waypoint or at one intermediate space, and the exit space.
Clause 18: The method of any of clauses 11-17, wherein the at least one characteristic is a value associated with an agent captured at an entry space corresponding to the first timestamp, until an exit space corresponding to a last timestamp, through at least one waypoint or at least one intermediate space of the event sequence tunnel.
Clause 19: The method of any of clauses 11-18, wherein the at least one characteristic is an agent identification, an agent type, an agent velocity, an agent dimension, an agent shape, an agent color, or any combinations thereof.
Clause 20: The method of any of clauses 11-19, wherein validating the response of the autonomous system to the simulation of the scenario comprises executing a tracking algorithm of the autonomous system on time series data of the scenario and determining that the tracking algorithm identified a threshold amount of consistent characteristics across frames of the scenario.
Clause 21: At least one non-transitory storage media storing instructions that, when executed by at least one processor, cause the at least one processor to: observe at least one characteristic of a simulated agent at a first timestamp during a simulation of a scenario; specify the simulated agent at subsequent timestamps according to the at least one characteristic in the scenario; determine at least one expected parameter associated with the simulated agent at the subsequent timestamps, wherein the at least one expected parameter is modified responsive to other simulation features; evaluate the simulated agent at the first timestamp and the subsequent timestamps, wherein associations among characteristics associated with the simulated agent are determined starting at the first timestamp through the subsequent timestamps, and wherein the associations evolve across iterative simulations of the scenario; and validate a response of an autonomous system in the iterative simulations of the scenario wherein the simulated agent consistently simulated according to the at least one characteristic at the first timestamp and subsequent timestamps.
Clause 22: The at least one non-transitory storage media of clause 21, wherein the at least one characteristic is a location of the simulated agent and the at least one expected parameter is a next location of the simulated agent.
Clause 23: The at least one non-transitory storage media of any of clauses 21 or 22, wherein the at least one characteristic is an object color of the simulated agent and the at least one expected parameter is a subsequent color of the simulated agent.
Clause 24: The at least one non-transitory storage media of any of clauses 21-23, wherein the at least one characteristic is an object identification and an event sequence tunnel is specified by at entry space at the first timestamp and an exit space at a subsequent timestamp.
Clause 25: The at least one non-transitory storage media of clause 24, wherein the at least one expected parameter is one or more dimensions of the event sequence tunnel, wherein at least one factor is applied to dimensions of the event sequence tunnel at the entry space and propagated through the event sequence tunnel.
Clause 26: The at least one non-transitory storage media of clause 24, wherein evaluating the simulated agent at the first timestamp and the subsequent timestamps comprises associating a consistent identification of the simulated agent in the iterative simulations of the scenario.
Clause 27: The at least one non-transitory storage media of clause 24, wherein at least one waypoint or at least one intermediate space is injected into in the event sequence tunnel identified for the simulated agent, and the simulated agent is evaluated at the entry space, then at least at one waypoint or at one intermediate space, and the exit space.
Clause 28: The at least one non-transitory storage media of any of clauses 21-27, wherein the at least one characteristic is a value associated with an agent captured at an entry space corresponding to the first timestamp, until an exit space corresponding to a last timestamp, through at least one waypoint or at least one intermediate space of the event sequence tunnel.
Clause 29: The at least one non-transitory storage media of any of clauses 21-28, wherein the at least one characteristic is an agent identification, an agent type, an agent velocity, an agent dimension, an agent shape, an agent color, or any combinations thereof.
Clause 30: The at least one non-transitory storage media of any of clauses 21-29, wherein validating the response of the autonomous system to the simulation of the scenario comprises executing a tracking algorithm of the autonomous system on time series data of the scenario and determining that the tracking algorithm identified a threshold amount of consistent characteristics across frames of the scenario.
Clause 31: A system, comprising: at least one processor, and at least one non-transitory storage media storing instructions that, when executed by the at least one processor, cause the at least one processor to: specify an event sequence tunnel in a scenario, wherein an entry space and an exit space of the event sequence tunnel are identified for a simulated agent; determine dimensions of the event sequence tunnel based on the simulated agent, wherein at least one factor is applied to dimensions of the event sequence tunnel at the entry space and propagated through the event sequence tunnel; evaluate the simulated agent at the entry space, until the exit space of the event sequence tunnel in a simulation of the scenario, wherein at least one consistent characteristic associated with the simulated agent is determined at the entry space, evolves across iterative simulations of the scenario, and is replicated throughout event sequence tunnels of respective scenarios; and validate a response of an autonomous system to simulations of the scenario in view of the at least one consistent characteristic of the simulated agent.
Clause 32: The system of clause 31, wherein at least one waypoint or at least one intermediate space is injected into in the event sequence tunnel identified for the simulated agent, and the simulated agent is evaluated at the entry space, then at least at one waypoint or at one intermediate space, and the exit space.
Clause 33: The system of any of clauses 31 or 32, wherein the at least one consistent characteristic is a value associated with an agent captured at the entry space, until the exit space, through at least one waypoint or at least one intermediate space of the event sequence tunnel.
Clause 34: The system of any of clauses 31-33, wherein the at least one consistent characteristic is an agent identification, an agent type, an agent velocity, an agent dimension, an agent shape, an agent color, or any combinations thereof.
Clause 35: The system of any of clauses 31-34, wherein validating the response of the autonomous system to the simulation of the scenario comprises executing a tracking algorithm of the autonomous system on time series data of the scenario and determining that the tracking algorithm identified a threshold amount of consistent characteristics across frames of the scenario.
Clause 36: The system of any of clauses 31-35, wherein the entry space, the exit space, at least one waypoint, at least one intermediate space, or any combinations thereof, are associated with a point in time in the simulation of the scenario.
Clause 37: The system of any of clauses 31-36, wherein the entry space, the exit space, at least one waypoint, at least one intermediate space, or any combinations thereof, are associated with a time interval in the simulation of the scenario.
Clause 38: The system of any of clauses 31-37, wherein the entry space, the exit space, and an intermediate space are two-dimensional.
Clause 39: The system of any of clauses 31-37, wherein the entry space, the exit space, and an intermediate space are three-dimensional.
Clause 40: A method comprising: specifying, with at least one processor, an event sequence tunnel in a scenario, wherein an entry space and an exit space of the event sequence tunnel are identified for a simulated agent; determining, with the at least one processor, dimensions of the event sequence tunnel based on the simulated agent, wherein at least one factor is applied to dimensions of the event sequence tunnel at the entry space and propagated through the event sequence tunnel; evaluating, with the at least one processor, the simulated agent at the entry space, until the exit space of the event sequence tunnel in a simulation of the scenario, wherein at least one consistent characteristic associated with the simulated agent is determined at the entry space, evolves across iterative simulations of the scenario, and is replicated throughout event sequence tunnels of respective scenarios; and validating, with the at least one processor, a response of an autonomous system to simulations of the scenario in view of the at least one consistent characteristic of the simulated agent.
Clause 41: The method of clause 40, wherein at least one waypoint or at least one intermediate space is injected into in the event sequence tunnel identified for the simulated agent, and the simulated agent is evaluated at the entry space, then at least at one waypoint or at one intermediate space, and the exit space.
Clause 42: The method of any of clauses 40 or 41, wherein the at least one consistent characteristic is a value associated with an agent captured at the entry space, until the exit space, through at least one waypoint or at least one intermediate space of the event sequence tunnel.
Clause 43: The method of any of clauses 40-42, wherein the at least one consistent characteristic is an agent identification, an agent type, an agent velocity, an agent dimension, an agent shape, an agent color, or any combinations thereof.
Clause 44: The method of any of clauses 40-43, wherein validating the response of the autonomous system to the simulation of the scenario comprises executing a tracking algorithm of the autonomous system on time series data of the scenario and determining that the tracking algorithm identified a threshold amount of consistent characteristics across frames of the scenario.
Clause 45: The method of any of clauses 40-44, wherein the entry space, the exit space, at least one waypoint, at least one intermediate space, or any combinations thereof, are associated with a point in time in the simulation of the scenario.
Clause 46: The method of any of clauses 40-45, wherein the entry space, the exit space, at least one waypoint, at least one intermediate space, or any combinations thereof, are associated with a time interval in the simulation of the scenario.
Clause 47: At least one non-transitory storage media storing instructions that, when executed by at least one processor, cause the at least one processor to: specify an event sequence tunnel in a scenario, wherein an entry space and an exit space of the event sequence tunnel are identified for a simulated agent; determine dimensions of the event sequence tunnel based on the simulated agent, wherein at least one factor is applied to dimensions of the event sequence tunnel at the entry space and propagated through the event sequence tunnel; evaluate the simulated agent at the entry space, until the exit space of the event sequence tunnel in a simulation of the scenario, wherein at least one consistent characteristic associated with the simulated agent is determined at the entry space, evolves across iterative simulations of the scenario, and is replicated throughout event sequence tunnels of respective scenarios; and validate a response of an autonomous system to simulations of the scenario in view of the at least one consistent characteristic of the simulated agent.
Clause 48: The at least one non-transitory storage media of clause 47, wherein at least one waypoint or at least one intermediate space is injected into in the event sequence tunnel identified for the simulated agent, and the simulated agent is evaluated at the entry space, then at least at one waypoint or at one intermediate space, and the exit space.
Clause 49: The at least one non-transitory storage media of any of clauses 47 or 48, wherein the at least one consistent characteristic is a value associated with an agent captured at the entry space, until the exit space, through at least one waypoint or at least one intermediate space of the event sequence tunnel.
Clause 50: The at least one non-transitory storage media of any of clauses 47-49, wherein the at least one consistent characteristic is an agent identification, an agent type, an agent velocity, an agent dimension, an agent shape, an agent color, or any combinations thereof.

In the foregoing description, aspects and embodiments of the present disclosure have been described with reference to numerous specific details that can vary from implementation to implementation. Accordingly, the description and drawings are to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. Any definitions expressly set forth herein for terms contained in such claims shall govern the meaning of such terms as used in the claims. In addition, when we use the term “further comprising,” in the foregoing description or following claims, what follows this phrase can be an additional step or entity, or a sub-step/sub-entity of a previously-recited step or entity.

1. A system, comprising:
at least one processor, and
at least one non-transitory storage media storing instructions that, when executed by the at least one processor, cause the at least one processor to:
observe at least one characteristic of a simulated agent at a first timestamp during a simulation of a scenario;
specify the simulated agent at subsequent timestamps according to the at least one characteristic in the scenario;
determine at least one expected parameter associated with the simulated agent at the subsequent timestamps, wherein the at least one expected parameter is modified responsive to other simulation features;
evaluate the simulated agent at the first timestamp and the subsequent timestamps, wherein associations among characteristics associated with the simulated agent are determined starting at the first timestamp through the subsequent timestamps, and wherein the associations evolve across iterative simulations of the scenario; and
validate a response of an autonomous system in the iterative simulations of the scenario wherein the simulated agent consistently simulated according to the at least one characteristic at the first timestamp and subsequent timestamps.

2. The system of claim 1, wherein the at least one characteristic is a location of the simulated agent and the at least one expected parameter is a next location of the simulated agent.

3. The system of claim 1, wherein the at least one characteristic is an object color of the simulated agent and the at least one expected parameter is a subsequent color of the simulated agent.

4. The system of claim 1, wherein the at least one characteristic is an object identification and an event sequence tunnel is specified by at entry space at the first timestamp and an exit space at a subsequent timestamp.

5. The system of claim 4, wherein the at least one expected parameter is one or more dimensions of the event sequence tunnel, wherein at least one factor is applied to dimensions of the event sequence tunnel at the entry space and propagated through the event sequence tunnel.

6. The system of claim 4, wherein evaluating the simulated agent at the first timestamp and the subsequent timestamps comprises associating a consistent identification of the simulated agent in the iterative simulations of the scenario.

7. The system of claim 4, wherein at least one waypoint or at least one intermediate space is injected into in the event sequence tunnel identified for the simulated agent, and the simulated agent is evaluated at the entry space, then at least at one waypoint or at one intermediate space, and the exit space.

8. The system of claim 1, wherein the at least one characteristic is a value associated with an agent captured at an entry space corresponding to the first timestamp, until an exit space corresponding to a last timestamp, through at least one waypoint or at least one intermediate space of the event sequence tunnel.

9. The system of claim 1, wherein the at least one characteristic is an agent identification, an agent type, an agent velocity, an agent dimension, an agent shape, an agent color, or any combinations thereof.

10. The system of claim 1, wherein validating the response of the autonomous system to the simulation of the scenario comprises executing a tracking algorithm of the autonomous system on time series data of the scenario and determining that the tracking algorithm identified a threshold amount of consistent characteristics across frames of the scenario.

11. A method comprising:
capturing, with at least one processor, at least one characteristic of a simulated agent at a first timestamp during a simulation of a scenario;
specifying, with at the least one processor, the simulated agent at subsequent timestamps according to the at least one characteristic in the scenario;
determining, with at the least one processor, at least one expected parameter associated with the simulated agent at the subsequent timestamps, wherein the at least one expected parameter is modified responsive to other simulation features;
evaluating, with at the least one processor, the simulated agent at the first timestamp and the subsequent timestamps, wherein associations among characteristics associated with the simulated agent are determined starting at the first timestamp through the subsequent timestamps, and wherein the associations evolve across iterative simulations of the scenario; and
validating, with at the least one processor, a response of an autonomous system in the iterative simulations of the scenario wherein the simulated agent consistently simulated according to the at least one characteristic at the first timestamp and subsequent timestamps.

12. The method of claim 11, wherein the at least one characteristic is a location of the simulated agent and the at least one expected parameter is a next location of the simulated agent.

13. The method of claim 11, wherein the at least one characteristic is an object color of the simulated agent and the at least one expected parameter is a subsequent color of the simulated agent.

14. The method of claim 11, wherein the at least one characteristic is an object identification and an event sequence tunnel is specified by at entry space at the first timestamp and an exit space at a subsequent timestamp.

15. The method of claim 14, wherein the at least one expected parameter is one or more dimensions of the event sequence tunnel, wherein at least one factor is applied to dimensions of the event sequence tunnel at the entry space and propagated through the event sequence tunnel.

16. The method of claim 14, wherein evaluating the simulated agent at the first timestamp and the subsequent timestamps comprises associating a consistent identification of the simulated agent in the iterative simulations of the scenario.

17. The method of claim 14, wherein at least one waypoint or at least one intermediate space is injected into in the event sequence tunnel identified for the simulated agent, and the simulated agent is evaluated at the entry space, then at least at one waypoint or at one intermediate space, and the exit space.

18-20. (canceled)

21. At least one non-transitory storage media storing instructions that, when executed by at least one processor, cause the at least one processor to:
observe at least one characteristic of a simulated agent at a first timestamp during a simulation of a scenario;
specify the simulated agent at subsequent timestamps according to the at least one characteristic in the scenario;
determine at least one expected parameter associated with the simulated agent at the subsequent timestamps, wherein the at least one expected parameter is modified responsive to other simulation features;
evaluate the simulated agent at the first timestamp and the subsequent timestamps, wherein associations among characteristics associated with the simulated agent are determined starting at the first timestamp through the subsequent timestamps, and wherein the associations evolve across iterative simulations of the scenario; and
validate a response of an autonomous system in the iterative simulations of the scenario wherein the simulated agent consistently simulated according to the at least one characteristic at the first timestamp and subsequent timestamps.

22. The at least one non-transitory storage media of claim 21, wherein the at least one characteristic is a location of the simulated agent and the at least one expected parameter is a next location of the simulated agent.

23. The at least one non-transitory storage media of claim 21, wherein the at least one characteristic is an object color of the simulated agent and the at least one expected parameter is a subsequent color of the simulated agent.

24-50. (canceled)
